(19) United States
(12) Patent Application Publication
(10) Pub. No.: US 2025/0391805 A1
(43) Pub. Date: Dec. 25, 2025

(54) SEMICONDUCTOR DEVICE

(71) Applicant: ROHM CO., LTD., Kyoto-shi (JP)

(72) Inventors: Yosuke NINOMIYA, Kyoto-shi (JP); Kazuki HASHIMOTO, Kyoto-shi (JP); Naoaki TSURUMI, Kyoto-shi (JP)

(73) Assignee: ROHM CO., LTD., Kyoto-shi (JP)

(21) Appl. No.: 19/305,819

(22) Filed: Aug. 21, 2025

Related U.S. Application Data
(63) Continuation of application No. PCT/JP2024/006498, filed on Feb. 22, 2024.

(30) Foreign Application Priority Data
Mar. 1, 2023 (JP) 2023-031042
Mar. 3, 2023 (JP) 2023-032974

(51) Int. Cl. H01L 23/00; H01L 23/495

(52) U.S. Cl. CPC H01L 24/41; H01L 23/49513; H01L 24/32; H01L 24/40; H01L 24/73; H01L 24/48; H01L 2224/32245; H01L 2224/40247; H01L 2224/41176; H01L 2224/48247; H01L 2224/73221; H01L 2224/73263; H01L 2224/73265

(57) ABSTRACT

A semiconductor device includes leads, a semiconductor element, a sealing resin covering the semiconductor element, and a heat dissipator. The semiconductor element includes first and second electrodes on a first side in a thickness direction. The leads include a first lead, a second lead, and an island lead. The semiconductor element is mounted on the first side in the thickness direction of the island lead. The first lead includes a first comb portion bonded to the first electrode and including a first face facing the first side in the thickness direction. The second lead includes a second comb portion bonded to the second electrode and including a second face facing the first side in the thickness direction. The first face is located on the first side in the thickness direction from the second face. The heat dissipator is bonded to the first face and exposed from the sealing resin.

### CROSS-REFERENCE TO RELATED APPLICATIONS

The present application is a bypass continuation of International Patent Application No. PCT/JP2024/006498 filed on Feb. 22, 2024, which claims priority to Japanese Patent Application No. 2023-031042, filed on Mar. 1, 2023, in the Japan Patent Office, and Japanese Patent Application No. 2023-032974, filed on Mar. 3, 2023, in the Japan Patent Office, the entire disclosure of each are hereby incorporated by reference herein.

### TECHNICAL FIELD

The present disclosure relates to a semiconductor device.

### BACKGROUND ART

Semiconductor devices have been developed that use III-V group nitride semiconductors (which may be hereinafter referred to as “nitride semiconductors”) such as gallium nitride (GaN). JP-A-2018-82011 discloses a semiconductor device that uses a nitride semiconductor. The semiconductor device disclosed in JP-A-2018-82011 includes an element body made of a semiconductor, and a nitride semiconductor layer and electrodes laminated on the obverse side of the element body. The electrodes include a source electrode, a drain electrode, and a gate electrode disposed on the nitride semiconductor layer. This semiconductor element is configured as a GaN-HEMT (High Electron Mobility Transistor) device.

### BRIEF DESCRIPTION OF THE DRAWINGS

FIG. 1 is a partial exploded perspective view of a semiconductor device according to a first embodiment of the present disclosure.

FIG. 2 is a plan view of the semiconductor device according to the first embodiment of the present disclosure.

FIG. 3 is a plan view of the semiconductor device according to the first embodiment of the present disclosure.

FIG. 4 is a partial plan view of the semiconductor device according to the first embodiment of the present disclosure.

FIG. 5 is a partial plan view of the semiconductor device according to the first embodiment of the present disclosure.

FIG. 6 is a bottom view of the semiconductor device according to the first embodiment of the present disclosure.

FIG. 7 is a front view of the semiconductor device according to the first embodiment of the present disclosure.

FIG. 8 is a rear view of the semiconductor device according to the first embodiment of the present disclosure.

FIG. 9 is a left side view of the semiconductor device according to the first embodiment of the present disclosure.

FIG. 10 is a right side view of the semiconductor device according to the first embodiment of the present disclosure.

FIG. 11 is a sectional view taken along line XI-XI in FIG. 4.

FIG. 12 is a partial enlarged sectional view of the semiconductor device according to the first embodiment of the present disclosure.

FIG. 13 is a sectional view taken along line XIII-XIII in FIG. 4.

FIG. 14 is a partial enlarged sectional view of the semiconductor device according to the first embodiment of the present disclosure.

FIG. 15 is a sectional view taken along line XV-XV in FIG. 4.

FIG. 16 is a sectional view taken along line XVI-XVI in FIG. 4.

FIG. 17 is a partial enlarged sectional view of the semiconductor device according to the first embodiment of the present disclosure.

FIG. 18 is a partial exploded perspective view of a semiconductor device according to a second embodiment of the present disclosure.

FIG. 19 is a plan view of the semiconductor device according to the second embodiment of the present disclosure.

FIG. 20 is a plan view of the semiconductor device according to the second embodiment of the present disclosure.

FIG. 21 is a partial plan view of the semiconductor device according to the second embodiment of the present disclosure.

FIG. 22 is a partial plan view of the semiconductor device according to the second embodiment of the present disclosure.

FIG. 23 is a bottom view of the semiconductor device according to the second embodiment of the present disclosure.

FIG. 24 is a sectional view taken along line XXIV-XXIV in FIG. 21.

FIG. 25 is a partial enlarged sectional view of the semiconductor device according to the second embodiment of the present disclosure.

FIG. 26 is a sectional view taken along line XXVI-XXVI in FIG. 21.

FIG. 27 is a partial enlarged sectional view of the semiconductor device according to the second embodiment of the present disclosure.

FIG. 28 is a sectional view taken along line XXVIII-XXVIII in FIG. 21.

FIG. 29 is a sectional view taken along line XXIX-XXIX in FIG. 21.

FIG. 30 is a partial enlarged sectional view of the semiconductor device according to the second embodiment of the present disclosure.

FIG. 31 is a circuit diagram of an example of a DC/DC converter in which the semiconductor device according to the second embodiment of the present disclosure is used.

FIG. 32 is a partial enlarged sectional view of the semiconductor device according to a third embodiment of the present disclosure.

FIG. 33 is a sectional view of a semiconductor device according to a fourth embodiment of the present disclosure.

FIG. 34 is a partial perspective view of a semiconductor device according to a fifth embodiment of the present disclosure.

FIG. 35 is a partial enlarged sectional view of the semiconductor device according to the fifth embodiment of the present disclosure.

FIG. 36 is a sectional view of a semiconductor device according to a sixth embodiment of the present disclosure.

FIG. 37 is a partial enlarged sectional view of the semiconductor device according to the sixth embodiment of the present disclosure.

FIG. 38 is a partial enlarged sectional view of a semiconductor device according to a seventh embodiment of the present disclosure.

FIG. 39 is a sectional view of a semiconductor device according to an eighth embodiment of the present disclosure.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A face A faces (a first side or a second side) in a direction B” is not limited to the situation where the angle of the face A to the direction B is 90° and includes the situation where the face A is inclined with respect to the direction B.

### First Embodiment

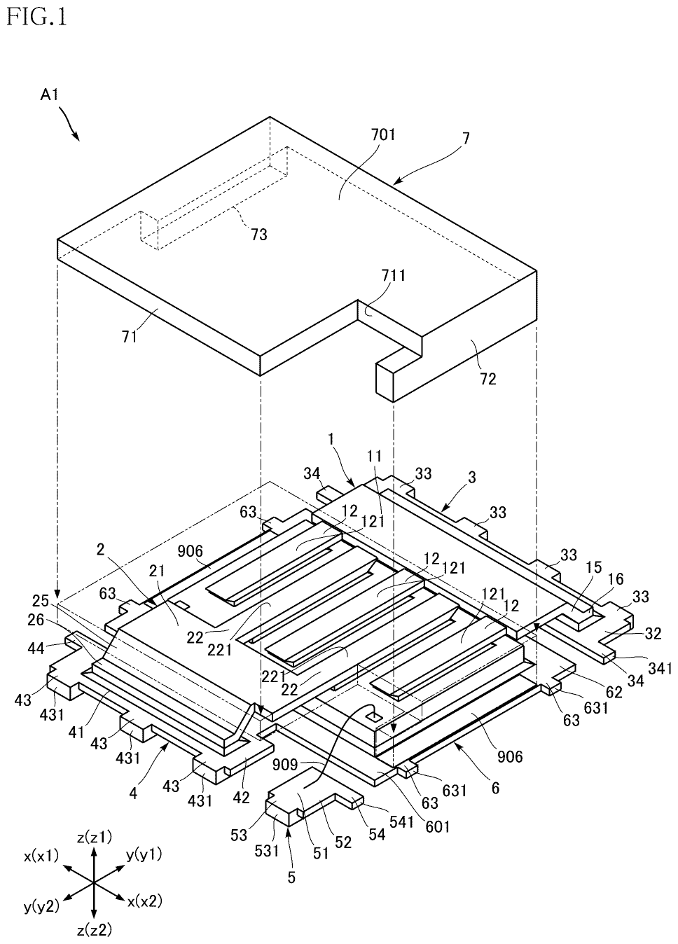

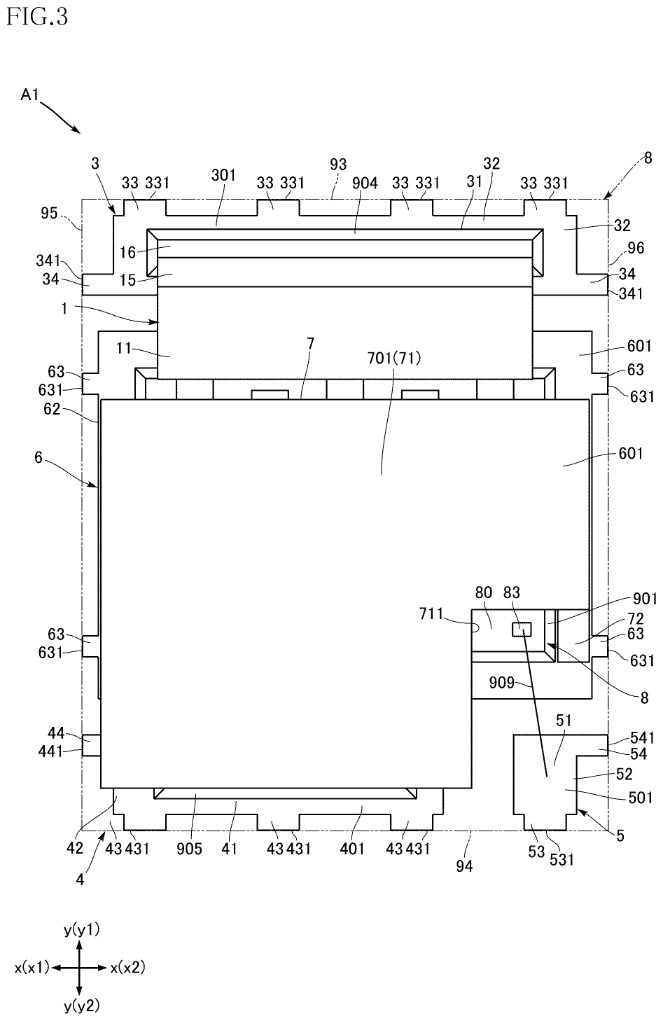

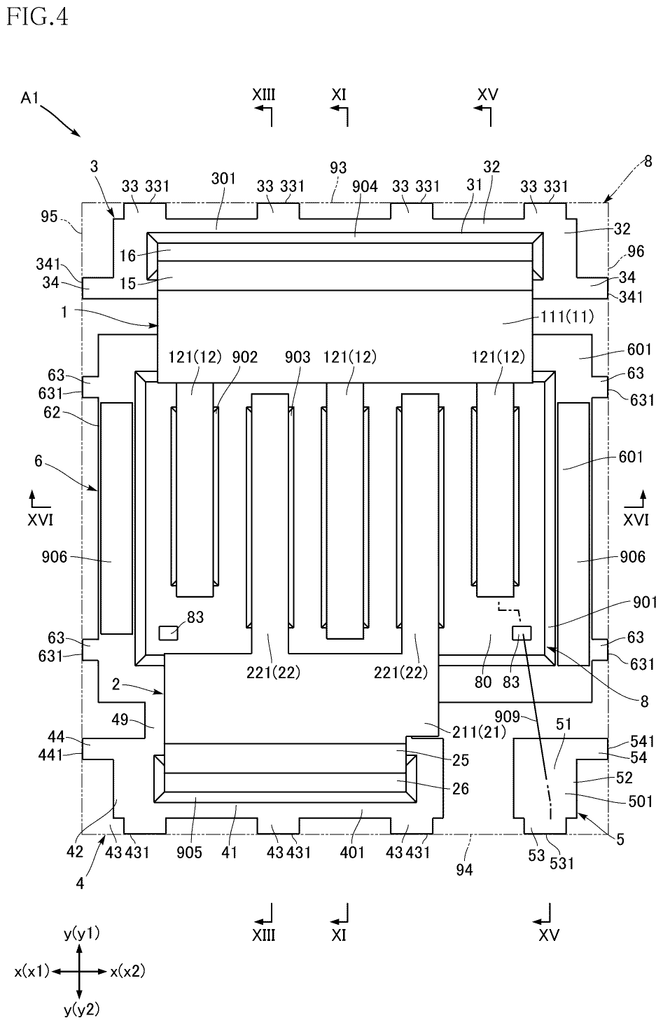

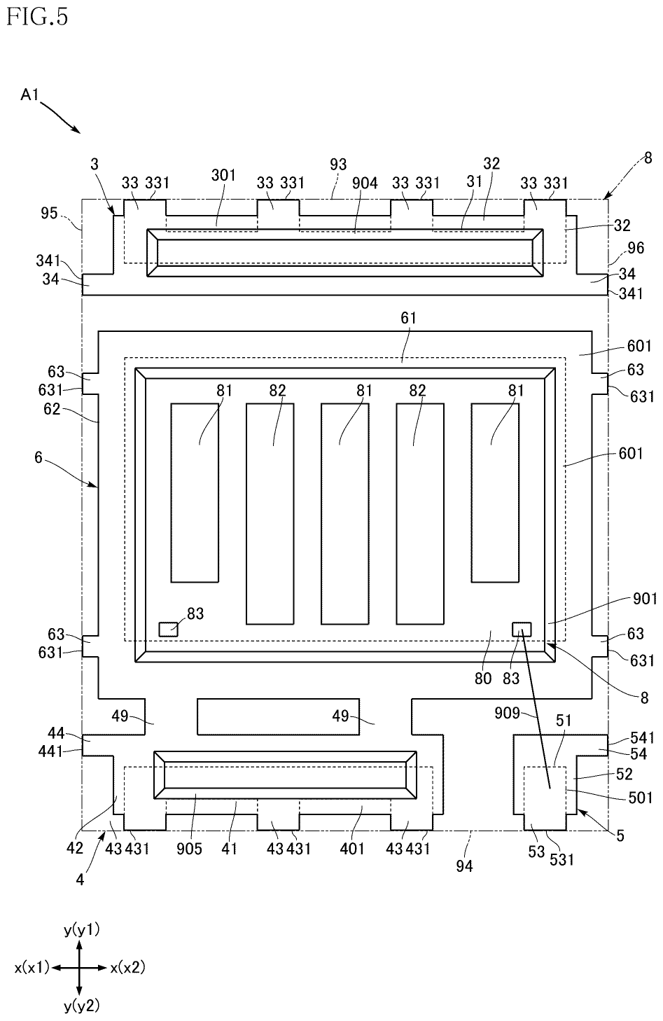

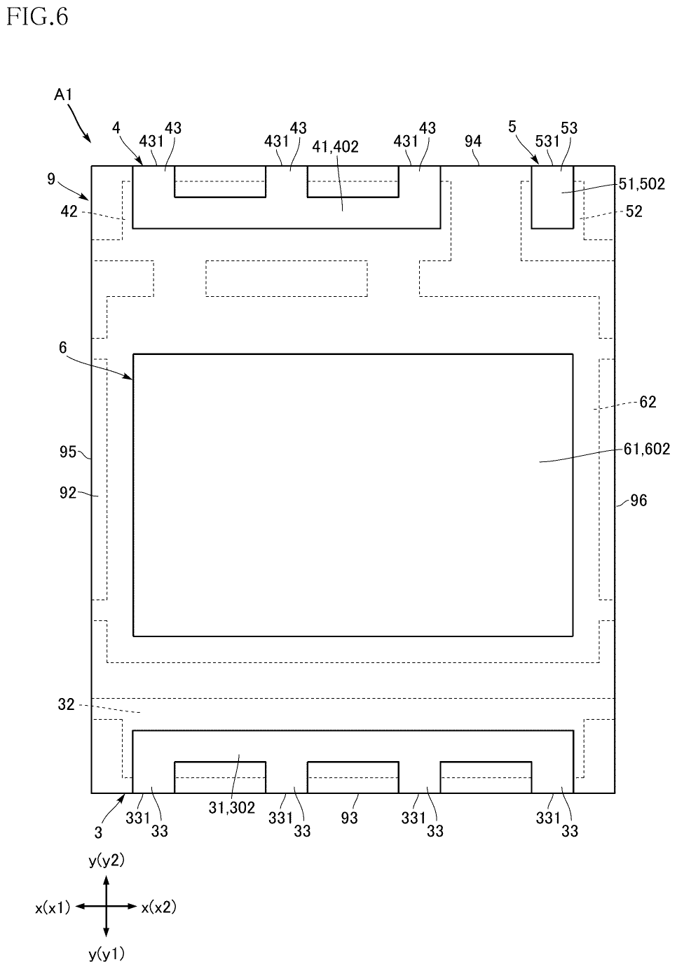

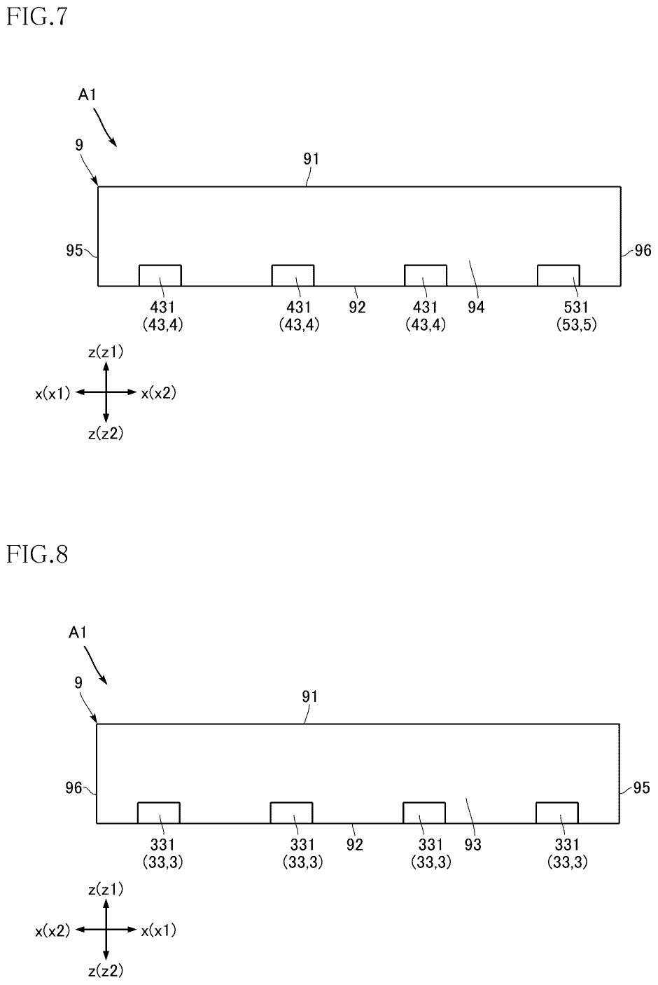

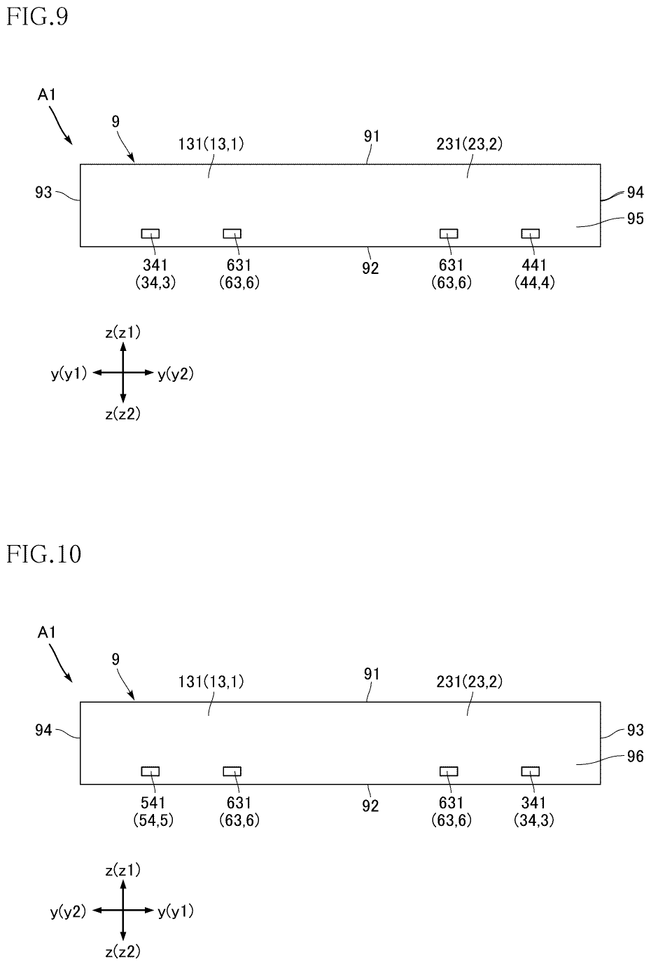

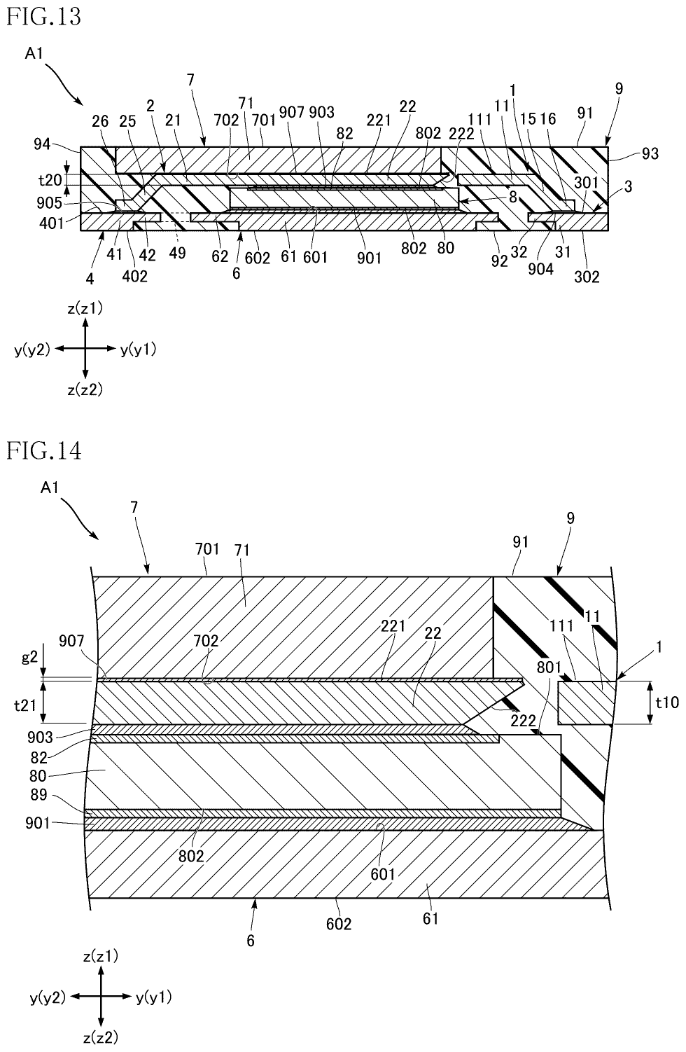

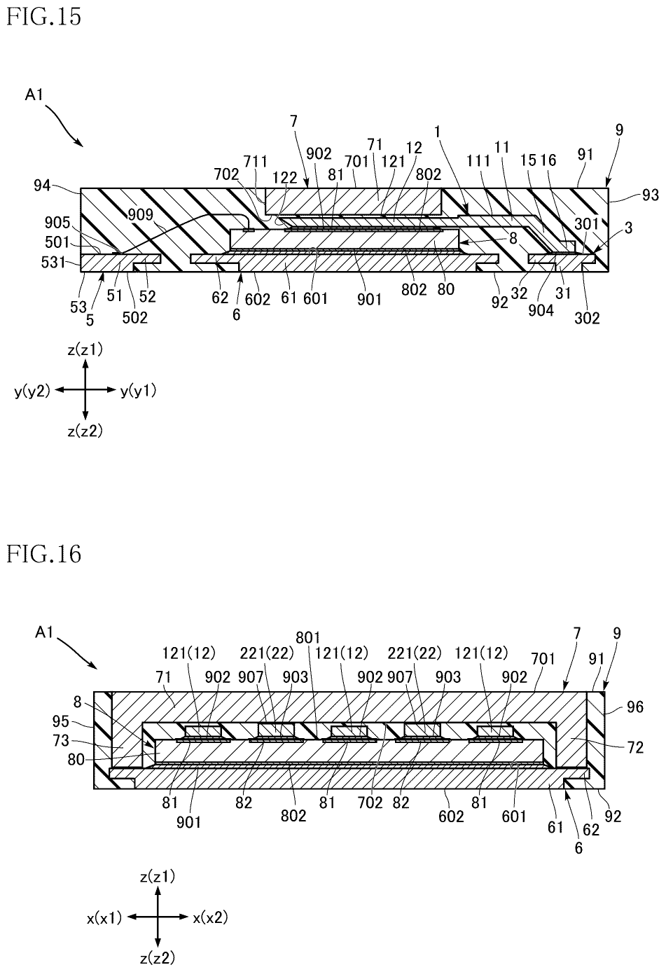

FIGS. 1 to 17 show a semiconductor device according to a first embodiment of the present disclosure. The semiconductor device A1 of the present embodiment includes a plurality of leads 1 to 6, a heat dissipation member 7, a semiconductor element 8, a wire 909, and a sealing resin 9. The semiconductor device A1 is mounted on a substrate, for example, to switch an electric current, but the specific application of the semiconductor device A1 is not limited in any way.

In these figures, three mutually orthogonal directions are referred to as appropriate. As an example, the thickness direction of the semiconductor device A1 (e.g., the vertical direction in FIG. 1) is defined as the thickness direction z. One direction orthogonal to the thickness direction z is defined as the first direction x. The direction orthogonal to the thickness direction z and the first direction x is defined as the second direction y.

### Leads 1 to 6:

The plurality of leads 1 to 6 are configured to achieve the functions such as supporting the semiconductor element 8 and forming a conduction path for electrical connection to the semiconductor element 8. The leads 1 to 6 contain a metal such as Cu (copper), Ni (nickel), Fe (iron) or alloys of these, for example. The leads 1 to 6 are formed, for example, by subjecting a metal plate to a process selected from punching, bending, etching, and the like. A plating layer containing, for example, Ag (silver), Ni (nickel), or Au (gold) may be provided at appropriate portions of each of the leads 1 to 6 as necessary.

In the present embodiment, the plurality of leads 1 to 6 will be described as a drain lead 1, a source lead 2, a drain terminal lead 3, a source terminal lead 4, a gate terminal lead 5, and an island lead 6. That is, the plurality of leads 1 to 6 include a drain lead 1, a source lead 2, a drain terminal lead 3, a source terminal lead 4, a gate terminal lead 5, and an island lead 6. As described later, in the present embodiment, the source terminal lead 4 and the island lead 6 are connected to each other. Depending on, for example, the form of electrical connection, the leads 1 to 6 may be configured as separate pieces, or some of the leads may be connected to each other.

### Island Lead 6:

As shown in FIGS. 1, 3 to 6, and 11 to 16, the island lead 6 has an obverse face 601, a reverse face 602, a thick portion 61, a thin portion 62, and a plurality of extended portions 63. The obverse face 601 faces the z1 side in the thickness direction z, and is a flat surface perpendicular to the thickness direction z in the illustrated example. The island lead 6 may, for example, have a recess or a groove recessed from the obverse face 601 as appropriate. The reverse face 602 faces the z2 side in the thickness direction z and faces away from the obverse face 601. In the illustrated example, the reverse face 602 is a flat surface perpendicular to the thickness direction z. A plating layer containing, for example, Ni (nickel) or Ti (titanium) may be provided on the reverse face 602 as appropriate.

The thick portion 61 is the portion where the obverse face 601 and the reverse face 602 overlap with each other as viewed in the thickness direction z, and is a rectangular portion as viewed in the thickness direction z in the illustrated example. The shape of the thick portion 61 is not limited in any way. The thickness of the thick portion 61 in the thickness direction z is the distance between the obverse face 601 and the reverse face 602. The thin portion 62 is the portion that overlaps with the obverse face 601 and does not overlap with the reverse face 602 as viewed in the thickness direction z. In the illustrated example, the thin portion 62 is connected to the thick portion 61 so as to extend from the thick portion 61 to the opposite sides in the first direction x and the opposite sides in the second direction y as viewed in the thickness direction z. The thickness of the thin portion 62 in the thickness direction z is smaller than the distance between the obverse face 601 and the reverse face 602. The thickness of the thick portion 61 and the thickness of the thin portion 62 are not limited in any way. As an example, the thickness of the thick portion 61 may be about 0.2 mm to 0.5 mm, and the thickness of the thin portion 62 may be 0.1 mm to 0.4 mm. In the illustrated example, the part of the thin portion 62 that extends from the thick portion 61 to the y1 side in the second direction y is larger than the part of the thin portion 62 that extends to the y2 side.

The extended portions 63 extend from the ends of the thin portion 62. In the illustrated example, the extended portions 63 extend from the thin portion 62 to opposite sides in the first direction x. The number of extended portions 63 is not limited in any way, and may be multiple or may be one. In the illustrated example, two extended portions 63 are provided on the x1 in the first direction x, and two extended portions 63 are provided on the x2 side. Each extended portion 63 has an end face 631. The end face 631 is the face that faces away from the thin portion 62 in the first direction x, i.e., the face that faces outward in the first direction x. The illustrated end face 631 is perpendicular to the first direction x. The two end faces 631 on the x1 side in the first direction x are located at the same position in the first direction x. The two end faces 631 on the x2 side in the first direction x are located at the same position in the first direction x.

### Drain Lead 1:

As shown in FIGS. 1, 3, 4, 11 to 14, and 16, the drain lead 1 is disposed on the z1 side in the thickness direction z from the drain terminal lead 3, the source terminal lead 4, the gate terminal lead 5, and the island lead 6. The drain lead 1 of the present embodiment has a main portion 11, a plurality of comb portions 12, a connecting portion 15, and a bond portion 16. The drain lead 1 of the present embodiment is an example of the second lead of the present disclosure.

The main portion 11 is a plate-like portion extending along the xy-plane, and has a rectangular (or generally rectangular) shape elongated in the first direction x in the illustrated example. The main portion 11 has a surface 111. The surface 111 faces z1 side in the thickness direction z. In the illustrated example, the surface 111 is a flat surface.

The comb portions 12 extend from the main portion 11 to the y2 side in the second direction y. The number of comb portions 12 is not limited in any way. In the illustrated example, three comb portions 12 are provided. The comb portions 12 are arranged side by side in the first direction x. The comb portion 12 of the present embodiment is an example of the second comb portion of the present disclosure.

The comb portions 12 are the portions located on the y2 side in the second direction y relative to the main portion 11. The shape of each comb portion 12 is not limited in any way, and in the illustrated example, it is elongated in the second direction y as viewed along the thickness direction z. The comb portions 12 are perpendicular to the thickness direction z.

In the illustrated example, the three comb portions 12 include a comb portion 12 that is different in length in the second direction y from other comb portions 12. The comb portion 12 located in the center in the first direction x has a longer length in the second direction y than the other comb portions 12. The comb portions 12 on opposite sides in the first direction x are disposed close to gate electrodes 83 described later. The comb portion 12 located on the x2 side in the first direction x is located close to the gate electrode 83 and the wire 909 described later. However, the comb portions 12 may be equal in length to each other.

Each comb portion 12 has a surface 121. The surface 121 of the present embodiment is an example of the second face of the present disclosure. The surface 121 faces the z1 side in the thickness direction z. In the illustrated example, the surface 121 is a flat surface. In the present embodiment, the surface 121 is located on the z2 side in the thickness direction z from the surface 111. In the illustrated example, the thickness t11 of the comb portions 12 is smaller than the thickness t10 of the main portion 11. Such a drain lead 1 can be formed for example by selectively conducting etching to the comb portions 12. The thickness t10 and the thickness t11 are not limited in any way. The thickness t10 is, for example, equal to or greater than 150 μm and equal to or less than 500 μm, and is, for example, about 250 μm. The thickness t11 is, for example, equal to or greater than 40% and equal to or less than 80% of the thickness t10, and is, for example, about 50%.

In the illustrated example, each comb portion 12 has a distal end face 122. The distal end face 122 is the surface located on the y2 side in the second direction y in the comb portion 12. The distal end face 122 is inclined so as to shift toward the z1 side in the thickness direction z as proceeding to the y2 side in the second direction y.

The connecting portion 15 is connected to the end on the y1 side in the second direction y that is opposite to the comb portion 12 with respect to the main portion 11. The connecting portion extends from the main portion 11 to the z2 side in the thickness direction z. The connecting portion 15 is inclined with respect to the thickness direction z. The shape of the connecting portion is not limited in any way, and is a rectangular shape elongated in the first direction x in the illustrated example. In the illustrated example, the center in the first direction x of the connecting portion 15 coincides with the center in the first direction x of the main portion 11.

The bond portion 16 is connected to the end on the y1 side in the second direction y of the connecting portion 15. The bond portion 16 is along the first direction x and the second direction y. As viewed in the thickness direction z, the bond portion 16 has a rectangular shape elongated in the first direction x. In the illustrated example, the center in the first direction x of the bond portion 16 coincides with the center in the first direction x of the connecting portion 15. The bond portion 16 is conductively bonded to the drain terminal lead 3 via a fourth conductive bonding portion 904. The fourth conductive bonding portion 904 may be, for example, solder, Ag paste, sintered Ag, or sintered Cu.

### Source Lead 2:

As shown in FIGS. 1, 4, 11, 13, 14 and 16, the source lead 2 is disposed on the z1 side in the thickness direction z from the drain terminal lead 3, the source terminal lead 4, the gate terminal lead 5, and the island lead 6. The source lead 2 is disposed on the y2 side in the second direction y relative to the drain lead 1. The source lead 2 of the present embodiment has a main portion 21, a plurality of comb portions 22, a connecting portion 25, and a bond portion 26. The source lead 2 of the present embodiment is an example of the first lead of the present disclosure.

The main portion 21 is a plate-like portion extending along the xy-plane, and has a rectangular (or generally rectangular) shape elongated in the first direction x in the illustrated example. The main portion 11 and the main portion 21 are disposed opposite to each other with respect to the semiconductor element 8 in the second direction y. The main portion 21 has a surface 211. The surface 211 faces the z1 side in the thickness direction z. In the illustrated example, the surface 211 is a flat surface.

The comb portions 22 extend from the main portion 21 to the y1 side in the second direction y. The number of comb portions 22 is not limited in any way. In the illustrated example, two comb portions 22 are provided. The comb portions 22 are arranged side by side in the first direction x. The comb portion 22 of the present embodiment is an example of the first comb portion of the present disclosure.

The comb portions 22 are the portions located on the y1 side in the second direction y relative to the main portion 21. The shape of each comb portion 22 is not limited in any way, and in the illustrated example, it is elongated in the second direction y as viewed along the thickness direction z. The comb portions 22 are perpendicular to the thickness direction z.

In the illustrated example, the two comb portions 22 have an equal length in the second direction y. However, the comb portions 22 may have different lengths in the second direction y.

Each comb portion 22 has a surface 221. The surface 221 of the present embodiment is an example of the first face of the present disclosure. The surface 221 faces the z1 side in the thickness direction z. In the illustrated example, the surface 221 is a flat surface. In the present embodiment, the surface 221 is located at the same position as the surface 211 in the thickness direction z. The surface 221 and the surface 211 are flush with each other. In the illustrated example, the thickness t20 of the main portion 21 and the thickness t21 of the comb portion 22 are equal to each other. In the illustrated example, the thickness t11 is smaller than the thickness t21. The thickness t20 and the thickness t21 are, for example, equal to or greater than 150 μm and equal to or less than 500 μm, and is, for example, about 250 μm.

In the illustrated example, each comb portion 22 has a distal end face 222. The distal end face 222 is the surface located on the y1 side in the second direction y in the comb portion 22. The distal end face 222 is inclined so as to shift toward the z1 side in the thickness direction z as proceeding to the y1 side in the second direction y.

The connecting portion 25 is connected to the end on the y2 side in the second direction y that is opposite to the comb portion 22 with respect to the main portion 21. The connecting portion 25 extends from the main portion 21 to the z2 side in the thickness direction z. The connecting portion 25 is inclined with respect to the thickness direction z. The shape of the connecting portion 25 is not limited in any way, and is a rectangular shape elongated in the first direction x in the illustrated example. In the illustrated example, the center in the first direction x of the connecting portion 25 is located on the x1 side in the first direction x relative to the center in the first direction x of the main portion 21.

The bond portion 26 is connected to the end on the y2 side in the second direction y of the connecting portion 25. The bond portion 26 is along the first direction x and the second direction y. As viewed in the thickness direction z, the bond portion 26 has a rectangular shape elongated in the first direction x. In the illustrated example, the center in the first direction x of the bond portion 26 coincides with the center in the first direction x of the connecting portion 25. The bond portion 26 is conductively bonded to the source terminal lead 4 via a fifth conductive bonding portion 905. The fifth conductive bonding portion 905 may be, for example, solder, Ag paste, sintered Ag, or sintered Cu.

### Drain Terminal Lead 3:

As shown in FIGS. 1, 3 to 6, 11, 13, and 15, the drain terminal lead 3 is spaced apart from the island lead 6 to the y1 side in the second direction y. The center in the first direction x of the drain terminal lead 3 is almost at the same position in the first direction x as the center in the first direction x of the island lead 6. The drain terminal lead 3 has an obverse face 301, a reverse face 302, a thick portion 31, a thin portion 32, a plurality of extended portions 33, and a plurality of end faces 341.

The obverse face 301 faces the z1 side in the thickness direction z, and is a flat surface perpendicular to the thickness direction z in the illustrated example. The drain terminal lead 3 may, for example, have a recess or a groove recessed from the obverse face 301 as appropriate. The bond portion 16 is bonded to the obverse face 301 via the fourth conductive bonding portion 904. The reverse face 302 faces the z2 side in the thickness direction z and faces away from the obverse face 301. In the illustrated example, the reverse face 302 is a flat surface perpendicular to the thickness direction z. A plating layer containing, for example, Ni (nickel) or Ti (titanium) may be provided on the reverse face 302 as appropriate. In the present embodiment, the obverse face 301 is almost at the same position as the obverse face 601 in the thickness direction z, and the reverse face 302 is almost at the same position as the reverse face 602.

The thick portion 31 is the portion where the obverse face 301 and the reverse face 302 overlap with each other as viewed in the thickness direction z. In the illustrated example, the thick portion 31 is a rectangular portion elongated in the first direction x as viewed in the thickness direction z. The shape of the thick portion 31 is not limited in any way. The thickness of the thick portion 31 in the thickness direction z is the distance between the obverse face 301 and the reverse face 302. The thin portion 62 is the portion that overlaps with the obverse face 301 and does not overlap with the reverse face 302 as viewed in the thickness direction z. In the illustrated example, the thin portion 32 is connected to the thick portion 31 so as to extend from the thick portion 31 to opposite sides in the first direction x and the y2 side in the second direction y as viewed in the thickness direction z. The thin portion 32 has a part connected to the thick portion 31 so as to extend from the thick portion 31 to the y1 side in the second direction y as viewed in the thickness direction z, and this part is flanked by the extended portions 33 in the first direction x. The thickness of the thin portion 32 in the thickness direction z is smaller than the distance between the obverse face 301 and the reverse face 302. The thickness of the thick portion 31 and the thickness of the thin portion 32 are not limited in any way. In the present embodiment, the thickness of the thick portion 31 is approximately equal to the thickness of the thick portion 61, and the thickness of the thin portion 32 is approximately equal to the thickness of the thin portion 62.

The extended portions 33 extend from an end of the thick portion 31. In the illustrated example, the extended portions 63 extend from the thick portion 31 to the y1 side in the second direction y. The number of extended portions 33 is not limited in any way, and may be multiple or may be one. In the illustrated example, four extended portions 33 are provided. Each extended portion 33 has an end face 331. The end face 331 is the face that faces away from the thick portion 31 in the second direction y, i.e., the face that faces the y1 side, which is the outer side, in the second direction y. The illustrated end face 331 is perpendicular to the second direction y. The end faces 331 are at the same position in the second direction y.

The extended portions 34 extend from the ends of the thin portion 32. In the illustrated example, the extended portions 34 extend from the thin portion 32 in the first direction. The number of extended portions 34 is not limited in any way, and may be multiple or may be one. In the illustrated example, two extended portions 34 are provided. Each extended portion 34 has an end face 341. The end face 341 faces in the first direction x. The illustrated end face 341 is perpendicular to the first direction x. Two end faces 341 face away from each other in the first direction x.

### Source Terminal Lead 4:

As shown in FIGS. 1, 3 to 6, 11, and 13, the source terminal lead 4 is disposed on the y2 side in the second direction y relative to the island lead 6. The center in the first direction x of the source terminal lead 4 is located on the x1 side in the first direction x from the center in the first direction x of the island lead 6. In the semiconductor device A1, the source terminal lead 4 and the island lead 6 are connected by a relay portion 49. In the illustrated example, two relay portions 49 spaced apart from each other in the first direction x are provided. The number of relay portions 49 is not limited in any way. Unlike such a configuration, the source terminal lead 4 may be separated from the island lead 6. The source terminal lead 4 has an obverse face 401, a reverse face 402, a thick portion 41, a thin portion 42, a plurality of extended portions 43, and an extended portion 44.

The obverse face 401 faces the z1 side in the thickness direction z, and is a flat surface perpendicular to the thickness direction z in the illustrated example. The source terminal lead 4 may, for example, have a recess or a groove recessed from the obverse face 401 as appropriate. The bond portion 26 is bonded to the obverse face 401 via the fifth conductive bonding portion 905. The reverse face 402 faces the z2 side in the thickness direction z and faces away from the obverse face 401. In the illustrated example, the reverse face 402 is a flat surface perpendicular to the thickness direction z. A plating layer containing, for example, Ni (nickel) or Ti (titanium) may be provided on the reverse face 402 as appropriate. In the present embodiment, the obverse face 401 is almost at the same position as the obverse face 601 in the thickness direction z, and the 10) reverse face 402 is almost at the same position as the reverse face 602.

The thick portion 41 is the portion where the obverse face 401 and the reverse face 402 overlap with each other as viewed in the thickness direction z. In the illustrated example, the thick portion 41 is a rectangular portion elongated in the first direction x as viewed in the thickness direction z. The shape of the thick portion 41 is not limited in any way. The thickness of the thick portion 41 in the thickness direction z is the distance between the obverse face 401 and the reverse face 402. In the present embodiment, the dimension in the first direction x of the thick portion 41 is smaller than the dimension in the first direction x of the thick portion 31. The thin portion 42 is the portion that overlaps with the obverse face 401 and does not overlap with the reverse face 402 as viewed in the thickness direction z. In the illustrated example, the thin portion 42 is connected to the thick portion 41 so as to extend from the thick portion 41 to opposite sides in the first direction x and the y1 side in the second direction y as viewed in the thickness direction z. The thin portion 42 has a part connected to the thick portion 41 so as to extend from the thick portion 41 to the y2 side in the second direction y as viewed in the thickness direction z, and this part is flanked by the extended portions 43 in the first direction x. The thickness of the thin portion 42 in the thickness direction z is smaller than the distance between the obverse face 401 and the reverse face 402. The thickness of the thick portion 41 and the thickness of the thin portion 42 are not limited in any way. In the present embodiment, the thickness of the thick portion 41 is approximately equal to the thickness of the thick portion 61, and the thickness of the thin portion 42 is approximately equal to the thickness of the thin portion 62.

The extended portions 43 extend from an end of the thick portion 41. In the illustrated example, the extended portions 43 extend from the thick portion 41 to the y2 side in the second direction y. The number of extended portions 43 is not limited in any way, and may be multiple or may be one. In the illustrated example, three extended portions 43 are provided. The positions in the first direction x of the three extended portions 43 are almost the same as the positions in the first direction x of the three extended portions 33 of the plurality of extended portions 33 that are located on the x1 side in the first direction x. Each extended portion 43 has an end face 431. The end face 431 is the face that faces away from the thick portion 41 in the second direction y, i.e., the face that faces the y2 side, which is the outer side, in the second direction y. The illustrated end face 431 is perpendicular to the second direction y. The plurality of end faces 431 are at the same position in the second direction y.

The extended portion 44 extends from an end of the thin portion 42. In the illustrated example, the extended portion 44 extends from the thin portion 42 to the x1 side in the first direction x. The number of extended portions 44 is not limited in any way, and may be multiple or may be one. In the illustrated example, one extended portion 44 is provided. The extended portion 44 has an end face 441. The end face 441 faces the x1 side in the first direction x. The illustrated end face 441 is perpendicular to the first direction x.

In the present embodiment, the island lead 6 is electrically connected to the source electrode 82 of the semiconductor element 8 via the source lead 2 and the source terminal lead 4.

### Gate Terminal Lead 5:

As shown in FIGS. 1, 3 to 6, and 15, the gate terminal lead 5 is disposed on the y2 side in the second direction y relative to the island lead 6. The center in the first direction x of the gate terminal lead 5 is located on the x2 side in the first direction x from the center in the first direction x of the island lead 6. The gate terminal lead 5 is disposed on the x2 side in the first direction x relative to the source terminal lead 4. The gate terminal lead 5 has an obverse face 501, a reverse face 502, a thick portion 51, a thin portion 52, an extended portion 53, and an extended portion 54.

The obverse face 501 faces the z1 side in the thickness direction z, and is a flat surface perpendicular to the thickness direction z in the illustrated example. The gate terminal lead 5 may, for example, have a recess or a groove recessed from the obverse face 501 as appropriate. A wire 909 is bonded to the obverse face 501. The reverse face 502 faces the z2 side in the thickness direction z and faces away from the obverse face 501. In the illustrated example, the reverse face 502 is a flat surface perpendicular to the thickness direction z. A plating layer containing, for example, Ni (nickel) or Ti (titanium) may be provided on the reverse face 502 as appropriate. In the present embodiment, the obverse face 501 is almost at the same position as the obverse face 601 in the thickness direction z, and the reverse face 502 is almost at the same position as the reverse face 602.

The thick portion 51 is the portion where the obverse face 501 and the reverse face 502 overlap with each other as viewed in the thickness direction z. In the illustrated example, the thick portion 51 is a rectangular portion as viewed in the thickness direction z. The shape of the thick portion 51 is not limited in any way. The thickness of the thick portion 51 in the thickness direction z is the distance between the obverse face 501 and the reverse face 502. In the present embodiment, the dimension in the first direction x of the thick portion 51 is smaller than the dimensions in the first direction x of the thick portion 31 and the thick portion 41. The thin portion 52 is the portion that overlaps with the obverse face 501 and does not overlap with the reverse face 502 as viewed in the thickness direction z. In the illustrated example, the thin portion 52 is connected to the thick portion 51 so as to extend from the thick portion 51 to opposite sides in the first direction x and the y1 side in the second direction y as viewed in the thickness direction z. The thickness of the thin portion 52 in the thickness direction z is smaller than the distance between the obverse face 501 and the reverse face 502. The thickness of the thick portion 51 and the thickness of the thin portion 52 are not limited in any way. In the present embodiment, the thickness of the thick portion 51 is approximately equal to the thickness of the thick portion 61, and the thickness of the thin portion 52 is approximately equal to the thickness of the thin portion 62.

The extended portion 53 extends from an end of the thick portion 51. In the illustrated example, the extended portion 53 extends from the thick portion 51 to the y2 side in the second direction y. The number of extended portions 53 is not limited in any way, and may be multiple or may be one. In the illustrated example, one extended portion 53 is provided. The position in the first direction x of the extended portion 53 is almost the same as the position in the first direction x of the outmost extended portion 33 on the x2 side in the first direction x. The extended portion 53 has an end face 531. The end face 531 is the face that faces away from the thick portion 51 in the second direction y, i.e., the face that faces the y2 side, which is the outer side, in the second direction y. The illustrated end face 531 is perpendicular to the second direction y. The position in the second direction y of the end face 531 is the same as those of the end faces 431.

The extended portion 54 extends from an end of the thin portion 52. In the illustrated example, the extended portion 54 extends from the thin portion 52 to the x2 side in the first direction x. The number of extended portions 54 is not limited in any way, and may be multiple or may be one. In the illustrated example, one extended portion 54 is provided. The position in the second direction y of the extended portion 54 is almost the same as the position in the second direction y of the extended portion 44. The extended portion 54 has an end face 541. The end face 541 is the face that faces away from the thick portion 51 in the first direction x, i.e., the face that faces the x2 side, which is the outer side, in the first direction x. The illustrated end face 541 is perpendicular to the first direction x. The position in the second direction y of the end face 541 is the same as those of the end face 341 and the end faces 631.

### Heat Dissipation Member 7:

The heat dissipation member 7 functions to dissipate the heat generated from the semiconductor element 8 to the outside of the semiconductor device A1. The material of the heat dissipation member 7 is not limited in any way and includes, for example, metals such as Cu (copper), Ni (nickel), Fe (iron) or alloys of these. The heat dissipation member 7 is formed, for example, by subjecting a metal plate to a process selected from punching, bending, etching, and the like. A plating layer containing, for example, Ag (silver), Ni (nickel), or Au (gold) may be provided at appropriate portions of the heat dissipation member 7 as necessary.

The shape of the heat dissipation member 7 is not limited in any way. As shown in FIGS. 1 to 3 and 11 to 17, in the present embodiment, the heat dissipation member 7 has a main portion 71, a support portion 72, and a support portion 73.

The main portion 71 is disposed on the z1 side in the z direction relative to the semiconductor element 8. The main portion 71 is not limited to any particular shape, and has the shape of a flat plate along the first direction x and the second direction y in the illustrated example. As viewed in the z direction, the main portion 71 overlaps with the semiconductor element 8, and overlaps with most of the semiconductor element 8 in the illustrated example. As viewed in the z direction, the main portion 71 overlaps with the comb portions 12 and the comb portions 22.

The main portion 71 has a heat dissipation obverse face 701 and a heat dissipation reverse face 702. The heat dissipation obverse face 701 faces the z1 side in the z direction. In the illustrated example, the heat dissipation obverse face 701 is a flat surface. The heat dissipation reverse face 702 faces the z2 side in the z direction. In the illustrated example, the heat dissipation reverse face 702 is a flat surface.

In the illustrated example, the main portion 71 has a recess 711. The recess 711 is the portion where the main portion 71 is recessed to the x1 side in the first direction x and to the y1 side in the second direction y. Due to the formation of the recess 711, the gate electrode 83 and the wire 909, which are located on the x2 side in the first direction x, do not overlap with the main portion 71 as viewed in the z direction.

The support portion 72 is connected to the end on the x2 side in the first direction x of the main portion 71 and extends to the z2 side in the z direction. The support portion 72 is elongated in the second direction y. In the illustrated example, a part of the support portion 72 protrudes from the main portion 71 to the y2 side in the second direction y.

The support portion 73 is connected to the end on the x1 side in the first direction x of the main portion 71 and extends to the z2 side in the z direction. The support portion 72 is elongated in the second direction y. In the illustrated example, the size in the second direction y of the support portion 73 is the same as the size in the second direction y of the support portion 72, and is smaller than the size in the second direction y of the end on the x1 side in the first direction x of the main portion 71.

The support portion 72 and the support portion 73 are bonded to the obverse face 601 of the island lead 6 with a sixth conductive bond portion 906. The sixth conductive bond portion 906 may be, for example, solder, Ag paste, sintered Ag, or sintered Cu.

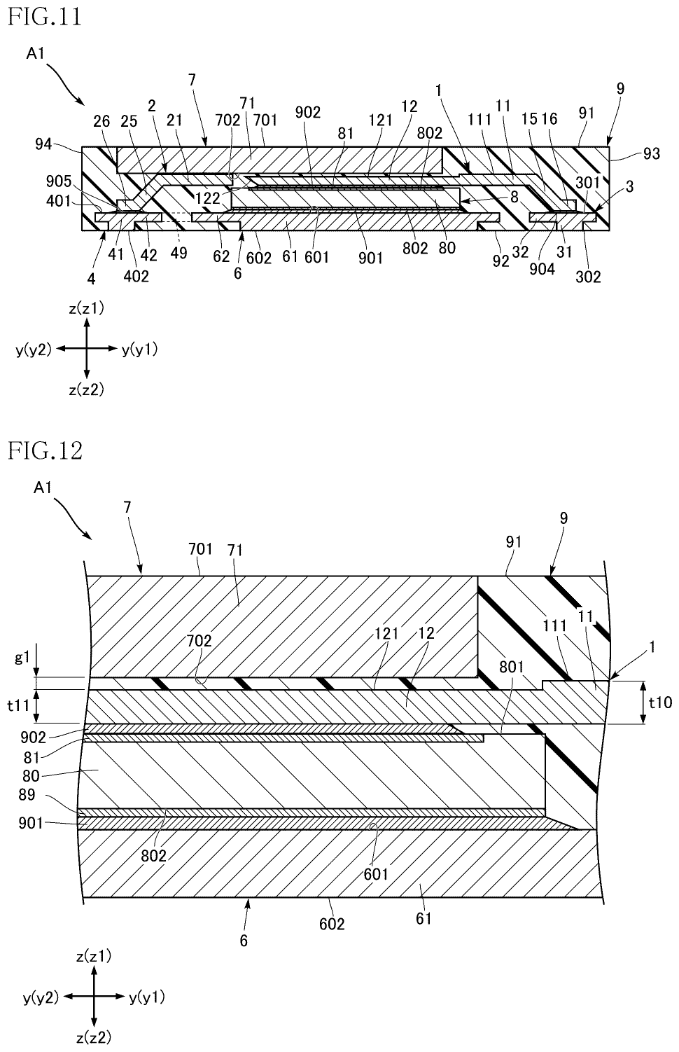

As shown in FIGS. 11 to 17, the heat dissipation reverse face 702 is bonded to the surfaces 221 of the comb portions 22 via a seventh conductive bonding portion 907. The seventh conductive bonding portion 907 may be, for example, solder, Ag paste, sintered Ag, or sintered Cu. In the illustrated example, the gap g2 between the surface 221 and the heat dissipation reverse face 702 is filled with the seventh conductive bonding portion 907. The size of the gap g2 is not limited in any way, and for example, equal to or greater than 10 μm and equal to or less than 30 μm. In the present embodiment, the heat dissipation reverse face 702 is bonded to the main portion 21 via the seventh conductive bonding portion 907. Depending on the shape or the like of the main portion 71, the heat dissipation reverse face 702 may not be bonded to the main portion 21.

The space between the heat dissipation reverse face 702 and the surfaces 121 of the comb portions 12 is filled with a part of the sealing resin 9. Thus, the heat dissipation member 7 and the comb portions 12 are insulated from each other. In the illustrated example, the main portion 71 does not cover the main portion 11 as viewed in the z direction. Therefore, when the thickness t10 of the main portion 11 is the same as the thickness t20 and the thickness t21, the main portion 11 is not bonded to or in contact with the main portion 71 of the heat dissipation member 7.

### Semiconductor Element 8:

The semiconductor element 8 is the element that performs the electrical function of the semiconductor device A1. The specific configuration of the semiconductor element 8 is not limited in any way. In the present embodiment, the semiconductor element 8 is a transistor that uses a nitride semiconductor, and more specifically, a GaN-HEMT (High Electron Mobility Transistor) element that uses gallium nitride (GaN). The semiconductor element 8 is not limited to those that use a nitride semiconductor, and may use other semiconductors such as silicon (Si) or silicon carbide (SiC). The semiconductor element 8 is not limited to HEMTs, and may be other transistors such as MOSFETs (Metal-Oxide-Semiconductor Field Effect Transistors) or IGBTs (Insulated Gate Bipolar Transistors). The semiconductor element 8 is mounted on the thick portion 61 of the island lead 6. As shown in FIGS. 1, 3 to 5, and 11 to 16, the semiconductor element 8 has an element body 80, a plurality of drain electrodes 81, a plurality of source electrodes 82, and a gate electrode 83.

The element body 80 is, the part where, for example, a substrate layer, a buffer layer, and a nitride semiconductor layer are laminated. The element body 80 has an element obverse face 801 and an element reverse face 802. The element obverse face 801 faces the z1 side in the thickness direction z. The element reverse face 802 faces the z2 side in the thickness direction z and faces away from the element obverse face 801. In the illustrated example, a metal layer 89 is provided on the element reverse face 802. The metal layer 89 and the obverse face 601 of the island lead 6 are bonded by a first conductive bond portion 901. The first conductive bond portion 901 may be, for example, solder, Ag paste, sintered Ag, or sintered Cu. Although the metal layer 89 is provided for bonding by the first conductive bond portion 901, a configuration that does not include the metal layer 89 may be employed. Alternatively, the metal layer 89 may be configured to be at the same potential as, for example, the source electrodes 82. In the illustrated example, the semiconductor element 8 is disposed at a position overlapping with a part of the thick portion 61 and a part of the thin portion 62 of the island lead 6 as viewed in the thickness direction z.

The drain electrodes 81, the source electrodes 82, and the gate electrode 83 are disposed on the element obverse face 801. The respective numbers of drain electrodes 81 and source electrodes 82 are not limited in any way. In the illustrated example, three drain electrodes 81 and two source electrodes 82 are provided. The number of drain electrodes 81 is the same as the number of comb portions 12, and the number of source electrodes 82 is the same as the number of comb portions 22. The drain electrodes 81 of the present embodiment are an example of the second electrode of the present disclosure. The source electrodes 82 of the present embodiment are an example of the first electrode of the present disclosure. The drain electrodes 81 and the source electrodes 82 are alternately arranged in the first direction x. The drain electrodes 81 and the source electrodes 82 are not limited to a particular shape, but in the illustrated example, they are elongated in the second direction y, and more specifically, rectangular.

The comb portions 12 of the drain lead 1 are conductively bonded to the drain electrodes 81 individually via second conductive bond portions 902. The second conductive bond portions 902 may be, for example, solder, Ag paste, sintered Ag, or sintered Cu. The comb portions 22 of the source lead 2 are conductively bonded to the source electrodes 82 individually via third conductive bond portions 903. The third conductive bond portions 903 may be, for example, solder, Ag paste, sintered Ag, or sintered Cu.

The number of gate electrodes 83 is not limited, and may be one or may be multiple. In the illustrated example, two gate electrodes 83 are provided. The two gate electrodes 83 are spaced apart from each other in the first direction x. The wire 909 is bonded to the gate electrode 83 disposed on the x2 side in the first direction x, and this gate electrode 83 is electrically connected to the gate terminal lead 5 via the wire 909. Instead of the wire 909, a conductive member made of a metal plate may be used to electrically connect the gate electrode 83 and the gate terminal lead 5. In the illustrated example, the gate electrode 83 on the x1 side in the first direction x is not electrically used.

### Sealing Resin 9:

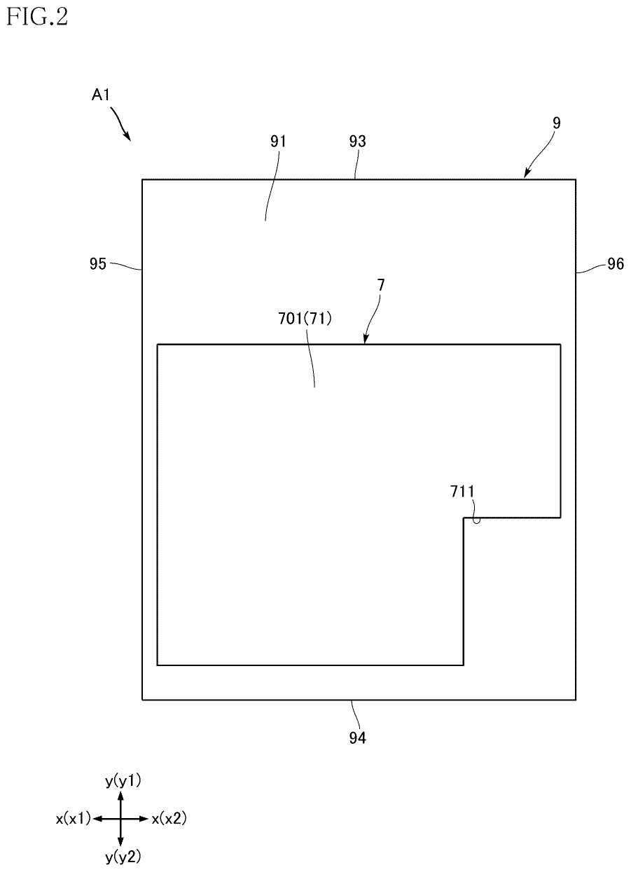

The sealing resin covers a part of each of the leads 1 to 6, a part of the heat dissipation member 7, the semiconductor element 8, and the wire 909, and is made of an insulating material such as an epoxy resin. As shown in FIGS. 2 to 16, the sealing resin 9 is in the form of of a rectangular parallelepiped with a resin first face 91, a resin second face 92, a resin third face 93, a resin fourth face 94, a resin fifth face 95, and a resin sixth face 96.

The resin first face 91 faces the z1 side in the thickness direction z. In the illustrated example, the resin first face 91 is a flat surface perpendicular to the thickness direction z. The resin second face 92 faces the z2 side in the thickness direction z. In the illustrated example, the resin second face 92 is a flat surface perpendicular to the thickness direction z. The resin third face 93 faces the y1 side in the second direction y. In the illustrated example, the resin third face 93 is a flat surface perpendicular to the second direction y. The resin fourth face 94 faces the y2 side in the second direction y. In the illustrated example, the resin fourth face 94 is a flat surface perpendicular to the second direction y. The resin fifth face 95 faces the x1 side in the first direction x. In the illustrated example, the resin fifth face 95 is a flat surface perpendicular to the first direction x. The resin sixth face 96 faces the x2 side in the first direction x. In the illustrated example, the resin sixth face 96 is a flat surface perpendicular to the first direction x.

The heat dissipation obverse face 701 of the heat dissipation member 7 is exposed from the resin first face 91 to the z1 side in the thickness direction z. The resin first face 91 and the heat dissipation obverse face 701 are flush with each other. However, the heat dissipation obverse face 701 may protrude slightly from the resin first face 91.

The reverse face 602 of the island lead 6, the reverse face 302 of the drain terminal lead 3, the reverse face 402 of the source terminal lead 4, and the reverse face 502 of the gate terminal lead 5 are exposed from the resin second face 92 to the z2 side in the thickness direction z. The resin second face 92, the reverse face 602 of the island lead 6, the reverse face 302 of the drain terminal lead 3, the reverse face 402 of the source terminal lead 4, and the reverse face 502 of the gate terminal lead 5 are flush with each other. However, all or any of the reverse face 602 of the island lead 6, the reverse face 302 of the drain terminal lead 3, the reverse face 402 of the source terminal lead 4, and the reverse face 502 of the gate terminal lead 5 may protrude slightly from the resin second face 92.

The end faces 331 of the drain terminal lead 3 are exposed from the resin third face 93 to the y1 side in the second direction y. The resin third face 93 and the end faces 331 of the drain terminal lead 3 are flush with each other. However, all or any of the end faces 331 may protrude slightly from the resin third face 93.

The end faces 431 of the source terminal lead 4 and the end face 531 of the gate terminal lead 5 are exposed from the resin fourth face 94 to the y2 side in the second direction y. The resin fourth face 94, the end faces 431 of the source terminal lead 4, and the end face 531 of the gate terminal lead 5 are flush with each other. However, all or any of the the end faces 431 of the source terminal lead 4 and the end face 531 of the gate terminal lead 5 may protrude slightly from the resin fourth face 94.

One of the end faces 341 of the drain terminal lead 3, the end face 441 of the source terminal lead 4, and the end faces 631 of the island lead 6 are exposed from the resin fifth face 95 to the x1 side in the first direction x. The resin fifth face 95, the end face 341 of the drain terminal lead 3, the end face 441 of the source terminal lead 4, and the end faces 631 of the island lead 6 are flush with each other. However, all or any of the end face 341 of the drain terminal lead 3, the end face 441 of the source terminal lead 4, and the end faces 631 of the island lead 6 may protrude slightly from the resin fifth face 95.

The other end face 341 of the drain terminal lead 3, the end face 541 of the gate terminal lead 5, and the end faces 631 of the island lead 6 are exposed from the resin sixth face 96 to the x2 side in the first direction x. The resin sixth face 96, the end face 341 of the drain terminal lead 3, the end face 541 of the gate terminal lead 5, and the end faces 631 of the island lead 6 are flush with each other. However, all or any of the end face 341 of the drain terminal lead 3, the end face 541 of the gate terminal lead 5, and the end faces 631 of the island lead 6 may protrude slightly from the resin sixth face 96.

The semiconductor device A1 is mounted on, for example, a circuit board (not shown) by using the reverse face 302, the reverse face 402, and the reverse face 502, which are exposed from the resin second face 92 of the sealing resin 9, as mounting terminals. That is, in the semiconductor device A1, the z2 side in the thickness direction z, which is opposite to the z1 side that the element obverse face 801 of the semiconductor element 8 faces, serves as the mounting surface. The reverse face 602 may be used as a heat dissipation surface for dissipating heat from the semiconductor element 8.

Next, the effects of the semiconductor device A1 will be described.

According to the present embodiment, the heat dissipation member 7 is bonded to the island lead 6 and exposed from the sealing resin 9. This allows the heat generated from the semiconductor element 8 to be dissipated more efficiently to the outside of the semiconductor device A1 via the island lead 6 and the heat dissipation member 7.

The heat dissipation member 7 has the main portion 71, the support portion 72, and the support portion 73. The main portion 71 overlaps with the semiconductor element 8 as viewed in the thickness direction z. The support portion 72 and the support portion 73 are disposed on opposite sides of the semiconductor element 8 in the first direction x orthogonal to the thickness direction z. Because the support portion 72 and the support portion 73 are bonded to the island lead 6, the heat transfer path from the island lead 6 to the main portion 71 can be shortened, which is desirable for improved heat dissipation.

The heat dissipation obverse face 701 is flush with the resin first face 91. This makes it possible to prevent the resin first face 91 from interfering when the heat dissipation obverse face 701 is pressed against a heat sink (not shown) or the like outside the semiconductor device A1.

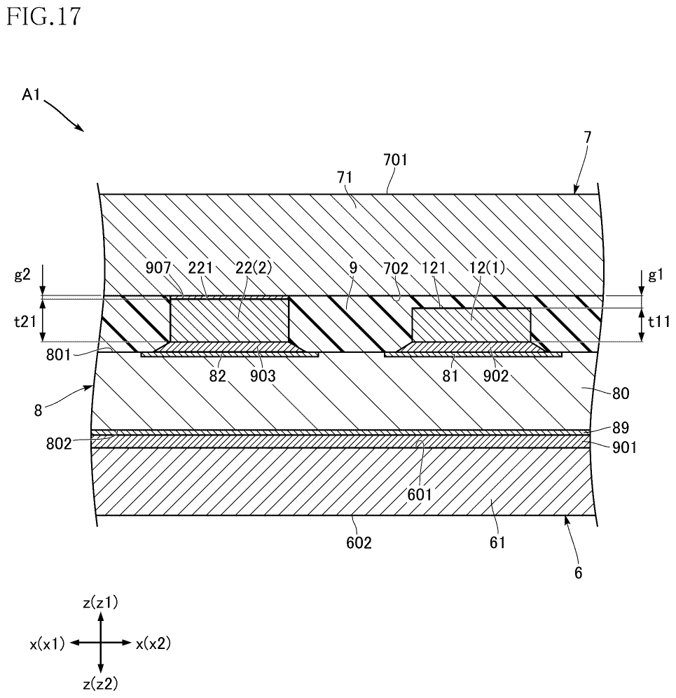

As shown in FIG. 17, the surfaces 221 of the comb portions 22 are bonded to the heat dissipation reverse face 702 of the heat dissipation member 7. On the other hand, the surfaces 121 of the comb portions 12 are located on the z2 side in the thickness direction z from the surfaces 221. The space between the heat dissipation reverse face 702 and the surfaces 121 is filled with a part of the sealing resin 9. This makes it possible to bond the heat dissipation member 7 and the source lead 2 together, while reliably insulating the heat dissipation member 7 from the drain lead 1. Thus, it is possible to increase the conduction path for electrical connection to the source electrode 82, which is the first electrode, and the heat transfer path for dissipation of heat from the semiconductor element 8 to the outside of the semiconductor device A1.

The thickness t21 of the comb portions 22 is larger than the thickness t11 of the comb portions 12. Thus, the gap g1 between the surface 121 and the heat dissipation reverse face 702 can be reliably made larger than the gap g2 between the surface 221 and the heat dissipation reverse face 702. This is favorable for keeping the surface 121 non-bonded to the heat dissipation reverse face 702 while bonding the surface 221 to the heat dissipation reverse face 702.

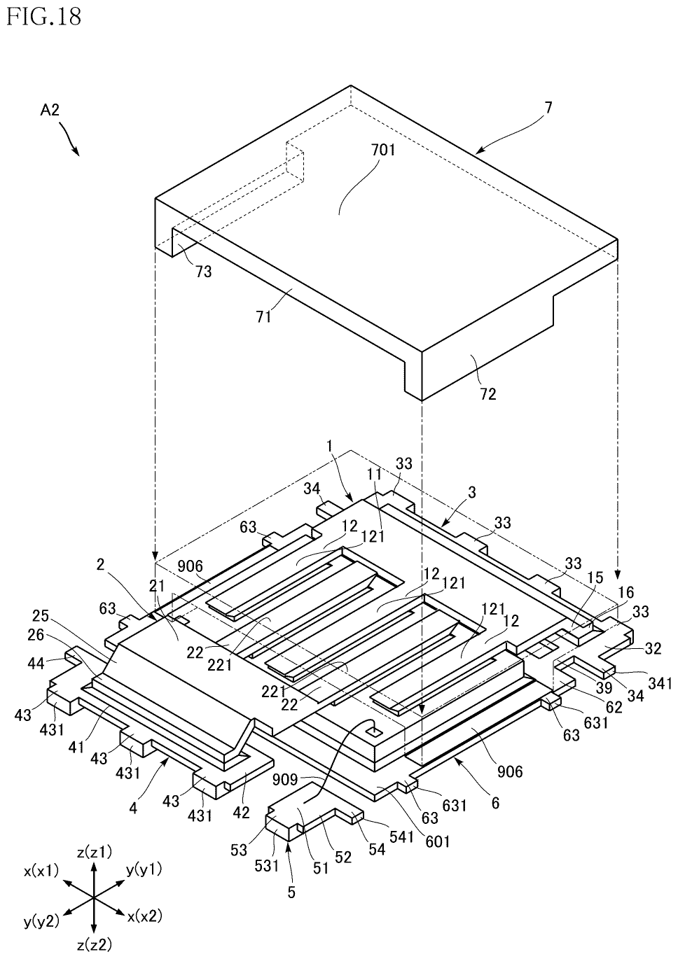

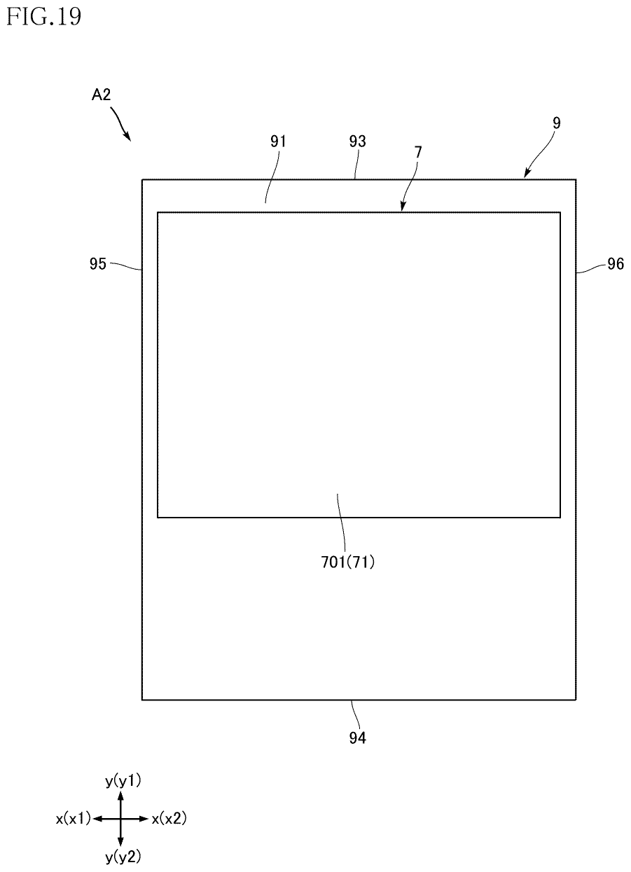

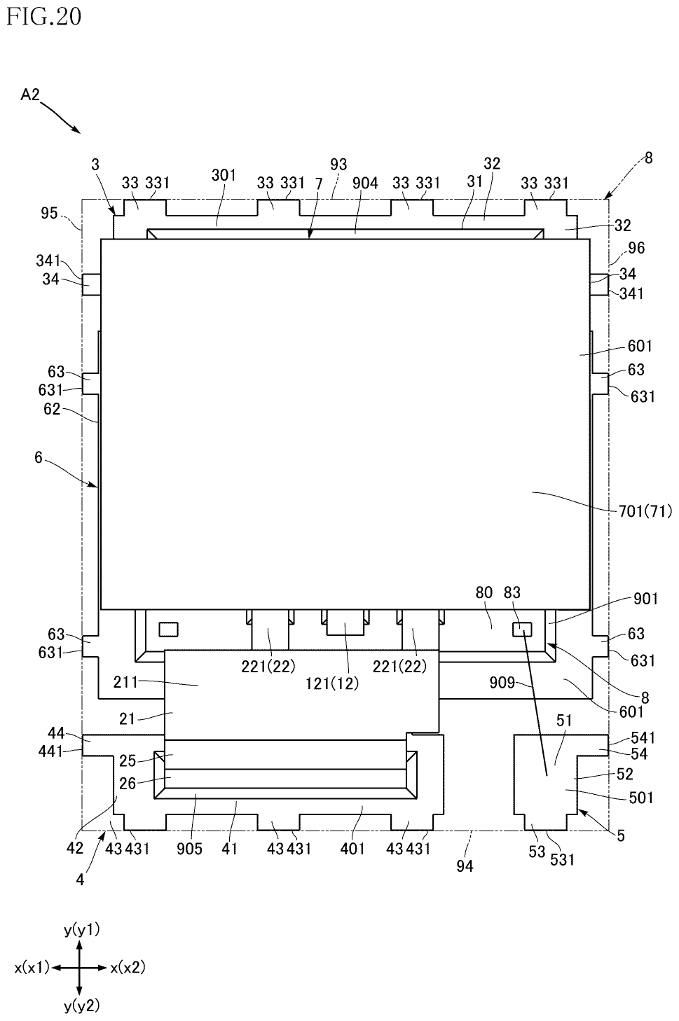

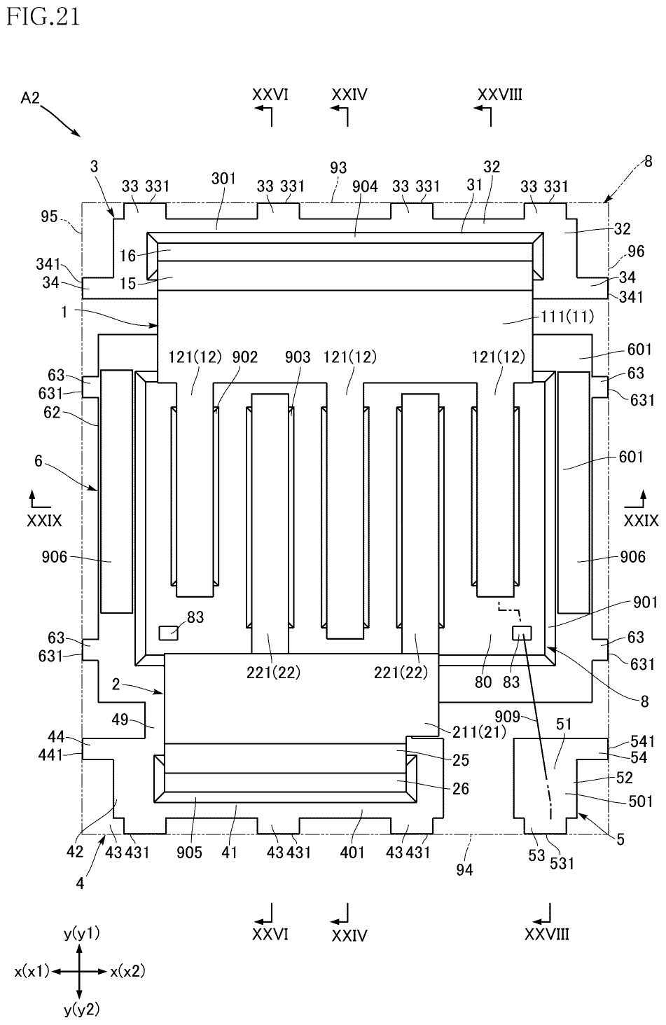

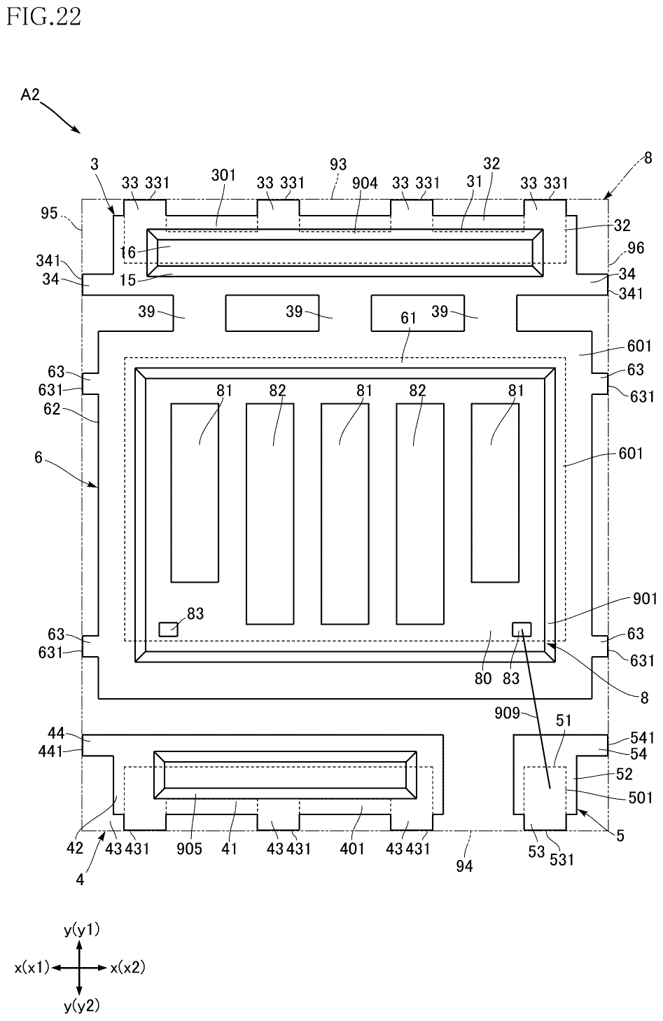

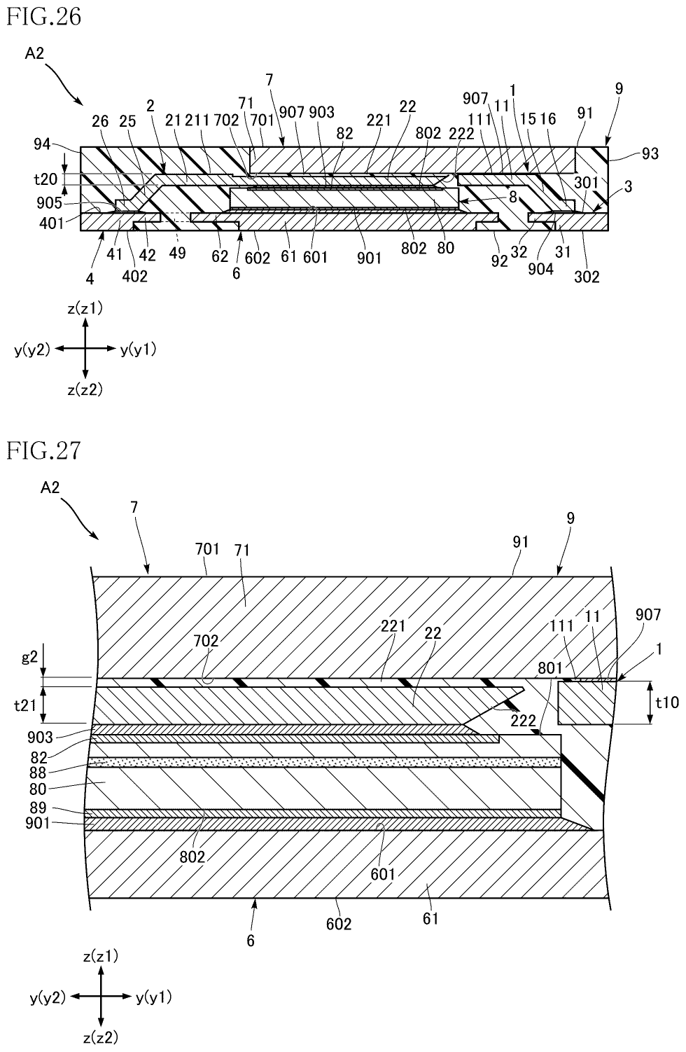

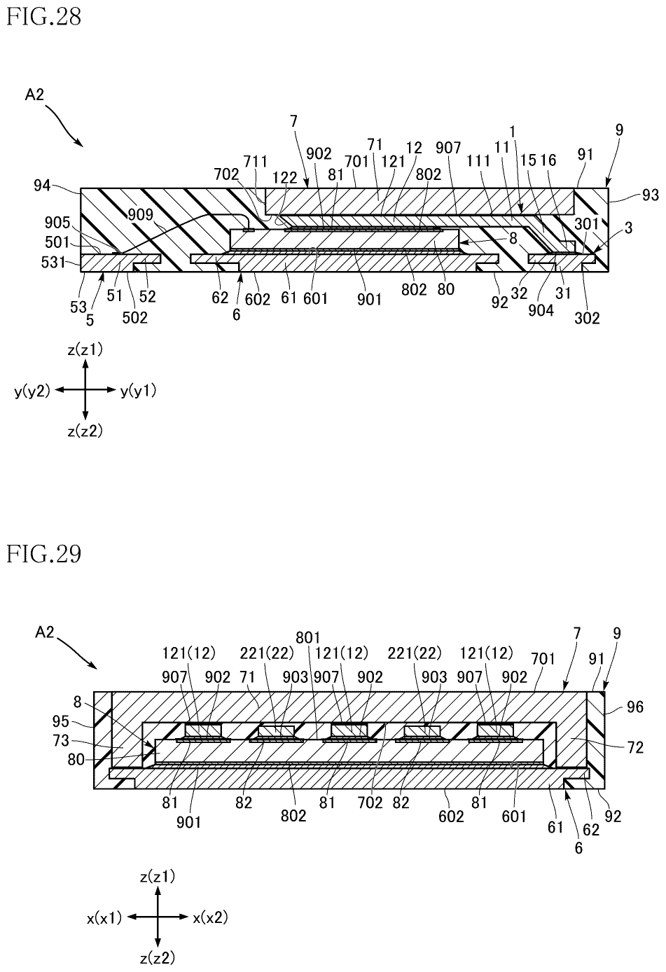

FIGS. 18 to 35 and 36 to 39 show other embodiments of the present disclosure. In these figures, the elements that are identical or similar to those of the above embodiment are denoted by the same reference signs as those used for the above embodiment. Various parts of variations and embodiments may be selectively used in any appropriate combination as long as it is technically compatible.

### Second Embodiment

FIGS. 18 to 30 show a semiconductor device according to a second embodiment of the present disclosure. The semiconductor device A2 of the present embodiment differs from the semiconductor device A1 in the bond form and electrical connection form of the leads 1 to 6 and the heat dissipation member 7.

### Drain Lead 1:

As shown in FIGS. 18, 20, 21, 24 to 27 and 29, the drain lead 1 is disposed on the z1 side in the thickness direction z from the drain terminal lead 3, the source terminal lead 4, the gate terminal lead 5, and the island lead 6. The drain lead 1 of the present embodiment has a main portion 11, a plurality of comb portions 12, a connecting portion 15, and a bond portion 16. The drain lead 1 of the present embodiment is an example of the first lead of the present disclosure.

Each comb portion 12 has a surface 121. The comb portion 12 of the present embodiment is an example of the first comb portion of the present disclosure. The surface 121 of the present embodiment is an example of the first face of the present disclosure. The surface 121 faces the z1 side in the thickness direction z. In the illustrated example, the surface 121 is a flat surface. In the present embodiment, the surface 121 is located at the same position as the surface 111 in the thickness direction z. The surface 121 and the surface 111 are flush with each other. In the illustrated example, the thickness t10 of the main portion 11 and the thickness t11 of the comb portion 12 are equal to each other. The thickness t10 and the thickness t11 are, for example, equal to or greater than 150 μm and equal to or less than 500 μm, and is, for example, about 250 μm.

### Source Lead 2:

As shown in FIGS. 18, 21, 24, 26 to 27 and 29, the source lead 2 is disposed on the z1 side in the thickness direction z from the drain terminal lead 3, the source terminal lead 4, the gate terminal lead 5, and the island lead 6. The source lead 2 is disposed on the y2 side in the second direction y relative to drain lead 1. The source lead 2 of the present embodiment has a main portion 21, a plurality of comb portions 22, a connecting portion 25, and a bond portion 26. The source lead 2 of the present embodiment is an example of the second lead of the present disclosure.

Each comb portion 22 has a surface 221. The comb portion 22 of the present embodiment is an example of the second comb portion of the present disclosure. The surface 221 of the present embodiment is an example of the second face of the present disclosure. The surface 221 faces the z1 side in the thickness direction z. In the illustrated example, the surface 221 is a flat surface. In the present embodiment, the surface 221 is located on the z2 side in the thickness direction z from the surface 211. In the illustrated example, the thickness t21 of the comb portions 22 is smaller than the thickness t20 of the main portion 21. In the illustrated example, the thickness t21 is smaller than the thickness t11. Such a source lead 2 can be formed for example by selectively conducting etching to the comb portions 22. The thickness t20 and the thickness t21 are not limited in any way. The thickness t20 is, for example, equal to or greater than 150 μm and equal to or less than 500 μm, and is, for example, about 250 μm. The thickness t21 is, for example, equal to or greater than 40% and equal to or less than 80% of the thickness t20, and is, for example, about 50%.

### Drain Terminal Lead 3:

As shown in FIGS. 18, 20 to 23, 24, 26 and 28, the drain terminal lead 3 is spaced apart from the island lead 6 to the y1 side in the second direction y. The center in the first direction x of the drain terminal lead 3 is almost at the same position in the first direction x as the center in the first direction x of the island lead 6. In the semiconductor device A2, the drain terminal lead 3 and the island lead 6 are connected by a relay portion 39. In the illustrated example, three relay portions 39 spaced apart from each other in the first direction x are provided. The number of relay portions 39 is not limited in any way.

In the present embodiment, the island lead 6 is electrically connected to the drain electrode 81 of the semiconductor element 8 via the drain lead 1 and the drain terminal lead 3.

### Source Terminal Lead 4:

As shown in FIGS. 18, 20 to 23, 24 and 26, the source terminal lead 4 is disposed on the y2 side in the second direction y relative to the island lead 6. The center in the first direction x of the source terminal lead 4 is located on the x1 side in the first direction x from the center in the first direction x of the island lead 6. In the semiconductor device A2, the source terminal lead 4 and the island lead 6 are spaced apart from each other.

### Heat Dissipation Member 7:

The main portion 71 is disposed on the z1 side in the z direction relative to the semiconductor element 8. The main portion 71 is not limited to any particular shape, and has the shape of a flat plate along the first direction x and the second direction y in the illustrated example. As viewed in the z direction, the main portion 71 overlaps with the semiconductor element 8, and overlaps with most of the semiconductor element 8 in the illustrated example. However, the main portion 71 does not overlap with the gate electrode 83 and the wire 909. As viewed in the z direction, the main portion 71 overlaps with the comb portions 12 and the comb portions 22.

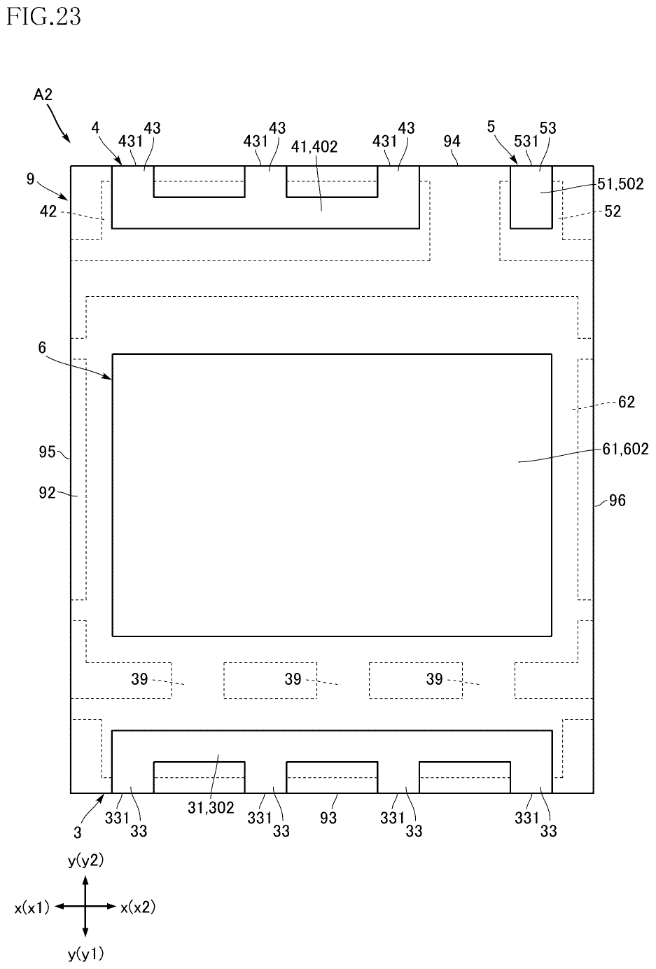

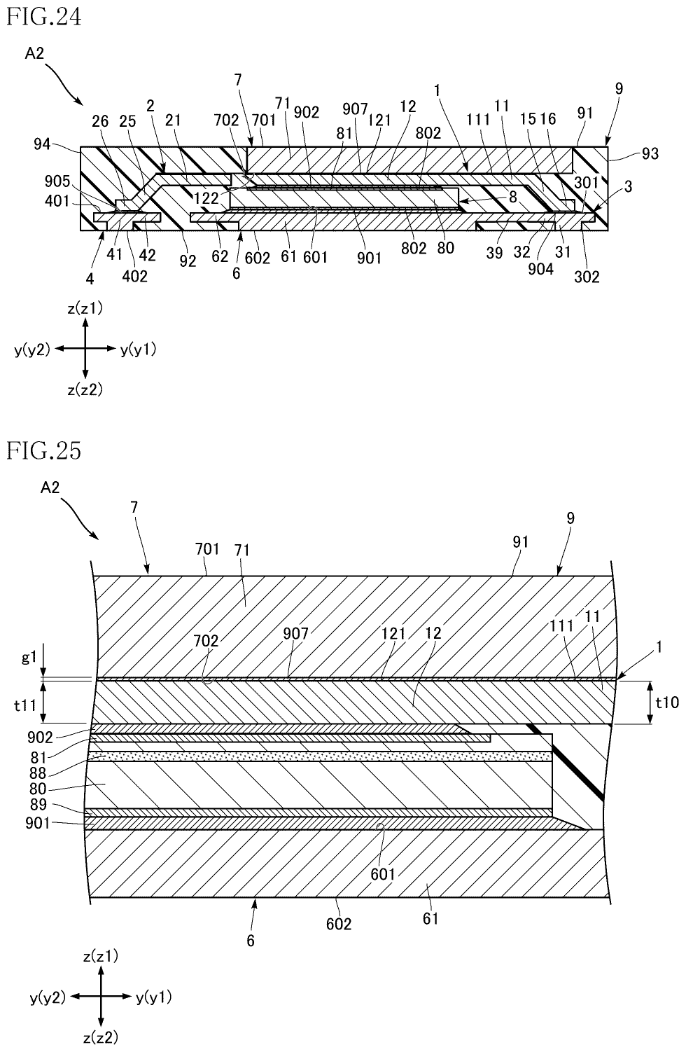

As shown in FIGS. 24 to 30, the heat dissipation reverse face 702 is bonded to the surfaces 121 of the comb portions 12 via the seventh conductive bonding portion 907. The seventh conductive bonding portion 907 may be, for example, solder, Ag paste, sintered Ag, or sintered Cu. In the illustrated example, the gap g1 between the surfaces 121 and the heat dissipation reverse face 702 is filled with the seventh conductive bonding portion 907. The size of the gap g1 is not limited in any way, and for example, equal to or greater than 10 μm and equal to or less than 30 μm. In the present embodiment, the heat dissipation reverse face 702 is bonded to the main portion 21 via the seventh conductive bonding portion 907. Depending on the shape or the like of the main portion 71, the heat dissipation reverse face 702 may not be bonded to the main portion 11.

The space between the heat dissipation reverse face 702 and the surfaces 221 of the comb portions 22 is filled with a part of the sealing resin 9. Thus, the heat dissipation member 7 and the comb portions 22 are insulated from each other. In the illustrated example, the main portion 71 does not cover the main portion 21 as viewed in the z direction. Therefore, when the thickness t20 of the main portion 21 is the same as the thicknesses t10 and t11, the main portion 21 is not bonded to or in contact with the main portion 71 of the heat dissipation member 7.

### Semiconductor Element 8:

The element body 80 of the semiconductor element 8 may further have a high-resistance layer 88. The high-resistance layer 88 is interposed, for example, between a substrate layer and a nitride semiconductor layer. With the provision of the high-resistance layer 88, at least the metal layer 89 is substantially insulated from the drain electrode 81 and source electrode 82.

The semiconductor device A2 is mounted on, for example, a circuit board (not shown) by using the reverse face 302, the reverse face 402, and the reverse face 502, which are exposed from the resin second face 92 of the sealing resin 9, as mounting terminals. That is, in the semiconductor device A2, the z2 side in the thickness direction z, which is opposite to the z1 side that the element obverse face 801 of the semiconductor element 8 faces, serves as the mounting surface. The reverse face 602 may be used as a heat dissipation surface for dissipating heat from the semiconductor element 8.

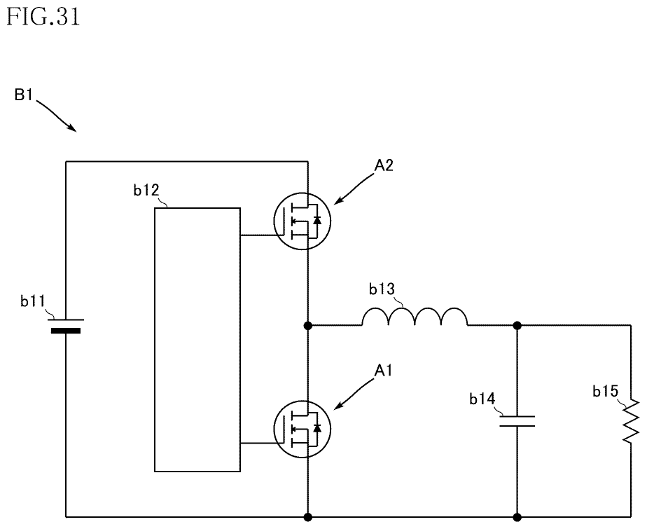

FIG. 31 is a circuit diagram of an example of a DC/DC converter in which the semiconductor device A2 is used. The DC/DC converter B1 in the figure has semiconductor devices A1 and A2, a power supply b11, a controller b12, an inductor b13, a capacitor b14, a load b15, and a semiconductor device b20.

The power supply b11 is a DC power supply. The controller b12 includes, for example, gate controllers for the semiconductor device A2 and the semiconductor device A1. The semiconductor device A2 is provided as a high-side switching device. The semiconductor device A1 is provided as a low-side switching device.

The inductor b13 is connected to a switching node that is the connection point between the source electrode 82 of the semiconductor device A2 and the drain electrode 81 of the semiconductor device A1. The capacitor b14 is connected in parallel with the load b15.

In the DC/DC converter B1, the drain electrode 81 of the semiconductor device A2 and the source electrode 82 of the semiconductor device A1 are connected to a power-supply node electrically connected to the power supply b11. In the operation of the DC/DC converter B1, voltage fluctuations are larger at the switching node than at the power supply node, and the switching node is more likely to generate noise. Therefore, in the circuit board (not shown) used for the DC/DC converter B1, increasing the area of the portion of the wiring pattern that is electrically connected to the switching node is not desirable. On the other hand, the portion of the wiring pattern that is electrically connected to the power supply node undergoes smaller voltage fluctuations than the switching node, and is less likely to generate noise. Therefore, the area of the portion of the wiring pattern that is electrically connected to the power supply node can be increased.

The island lead 6 of the semiconductor device A2 is connected to the portion of the wiring pattern that is electrically connected to the power supply node. Therefore, heat from the semiconductor element 8 of the semiconductor device A2 can be dissipated more efficiently through the island lead 6. The island lead 6 of the semiconductor device A1 is connected to the portion of the wiring pattern that is electrically connected to the power supply node. Therefore, heat from the semiconductor element 8 of the semiconductor device A1 can be dissipated more efficiently through the island lead 6.

Next, the effects of the semiconductor device A2 will be described.

According to the present embodiment, the island lead 6 is electrically connected to the drain electrode 81 of the semiconductor element 8. Thus, when the semiconductor device A2 is used in the DC/DC converter B1 shown in FIG. 31, greater freedom in mounting is provided, which allows, for example, bonding the island lead 6 to a larger portion of the wiring pattern. When the semiconductor device A1 is used in the DC/DC converter B1, heat dissipation from the semiconductor device A2 can be promoted.

The island lead 6 is electrically connected to the drain electrode 81 via the drain lead 1 and the drain terminal lead 3. The island lead 6 is disposed on the z2 side in the thickness direction z of the semiconductor element 8, and the drain electrode 81 is disposed at a portion on the z1 side in the thickness direction z of the semiconductor element 8. By providing the drain lead 1 and the drain terminal lead 3, the drain electrode 81 and the island lead 6 can be electrically connected more reliably.

The drain terminal lead 3 and the island lead 6 are connected by the relay portion 39. The relay portion 39 is smaller in size in the the first direction x than the drain terminal lead 3 and the island lead 6. This can, for example, enhance the flow of the resin material when molding the sealing resin 9.

The element body 80 of the semiconductor element 8 has a high-resistance layer 88. This prevents, for example, unintentional formation of minute cracks in the element body 80 and the resulting electrical connection of the metal layer 89 to the drain electrode 81 during the manufacturing of the semiconductor element 8.

### Third Embodiment

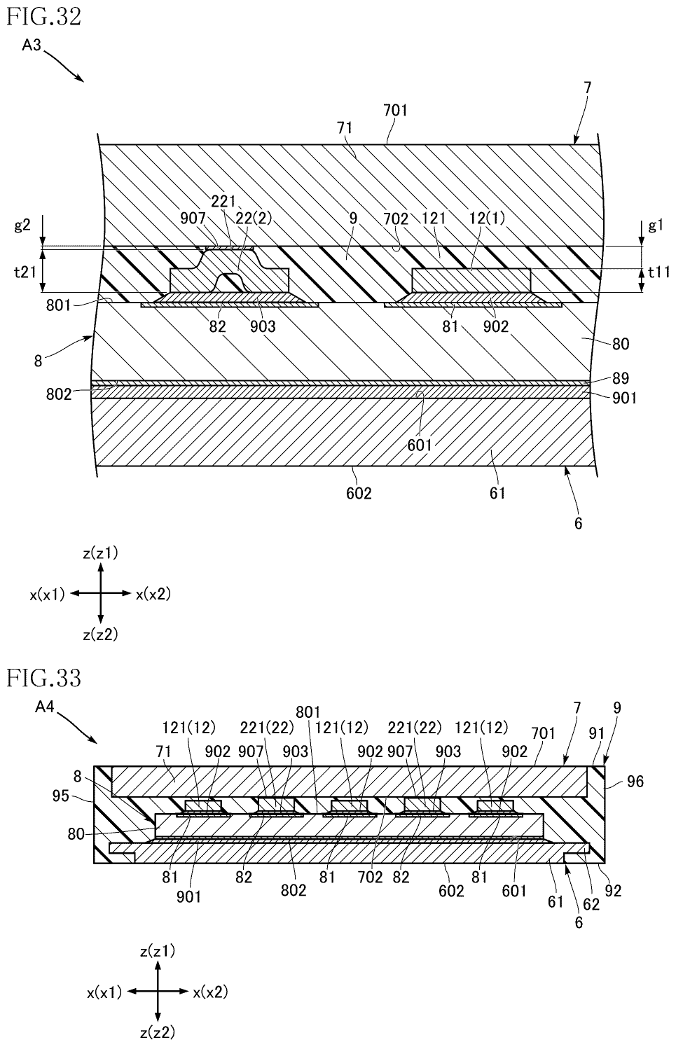

FIG. 32 shows a semiconductor device according to a third embodiment of the present disclosure. The semiconductor device A3 of the present embodiment differs from the embodiments described above in configuration of the comb portion 22.

The comb portion 22 of the present embodiment is bent as viewed in the second direction y orthogonal to the thickness direction y. The central part of the comb portion 22 in the first direction x is located on the z1 side in the thickness direction z from the opposite side portions in the first direction x. The central part forms the surface 221. Such a comb section 22 is formed, for example, by bending a metal plate having the same thickness as the thickness t11 of the main portion 21.

According to the present embodiment again, heat from the semiconductor element 8 can be dissipated more efficiently. As understood from present embodiment, the specific way of making the surface 121 and the surface 221 differ from each other in position in the thickness direction z is not limited in any way.

### Fourth Embodiment

FIG. 33 shows a semiconductor device according to a fourth embodiment of the present disclosure. The semiconductor device A4 of the present embodiment differs from the embodiments described above in configuration of the heat dissipation member 7.

The heat dissipation member 7 of the present embodiment has the main portion 71, but does not have the support portion 72 and the support portion 73. The heat dissipation member 7 is electrically connected to the source electrode 82 of the semiconductor element 8 by bonding the heat dissipation reverse face 702 of the main portion 71 to the surfaces 221 via the seventh conductive bonding portion 907. The heat dissipation member 7 is not bonded to the island lead 6.

According to the present embodiment again, heat from the semiconductor element 8 can be dissipated more efficiently. As understood from the present embodiment, the heat dissipation member 7 may not be bonded to the island lead 6.

### Fifth Embodiment

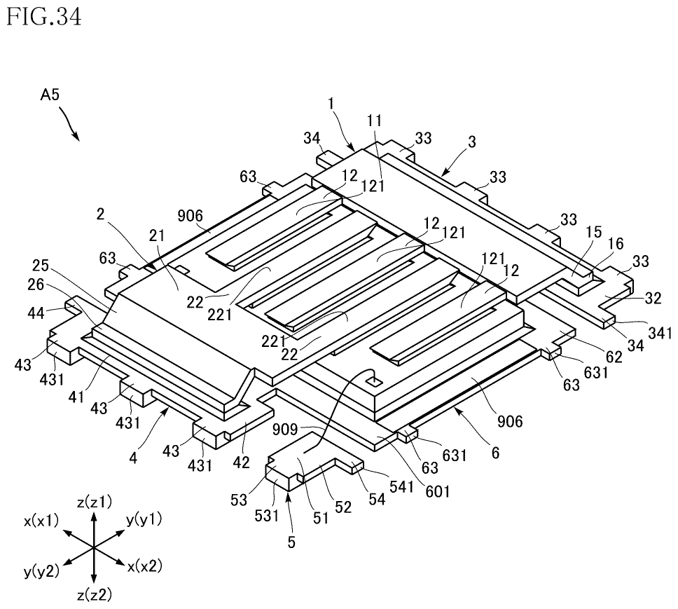

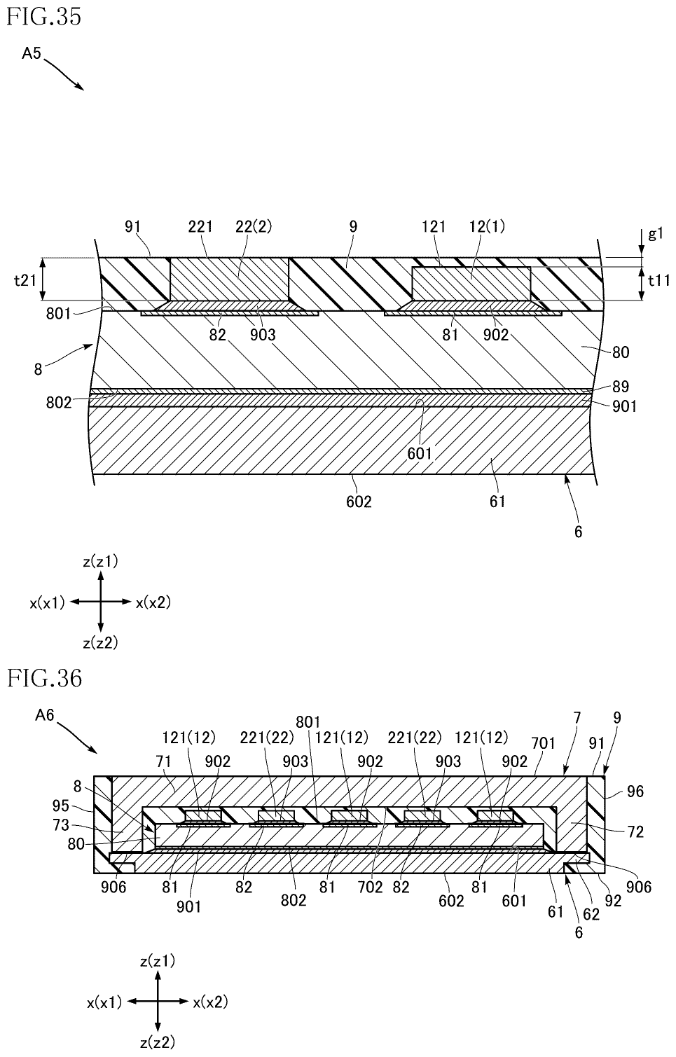

FIGS. 34 and 35 show a semiconductor device according to a fifth embodiment of the present disclosure. The semiconductor device A5 of the present embodiment does not include the heat dissipation member 7 of the above embodiments. The surfaces 221 of the comb portions 22 are exposed from the sealing resin 9. In the illustrated example, the surfaces 221 are flush with the resin first face 91 of the sealing resin 9. On the other hand, the surfaces 121 of the comb portions 12 are covered with the sealing resin 9. The surfaces 221 are located on the z1 side in the thickness direction z from the surfaces 121.

According to the present embodiment again, because the surfaces 221 are exposed from the sealing resin 9, heat from the semiconductor element 8 can be dissipated more efficiently.

### Sixth Embodiment

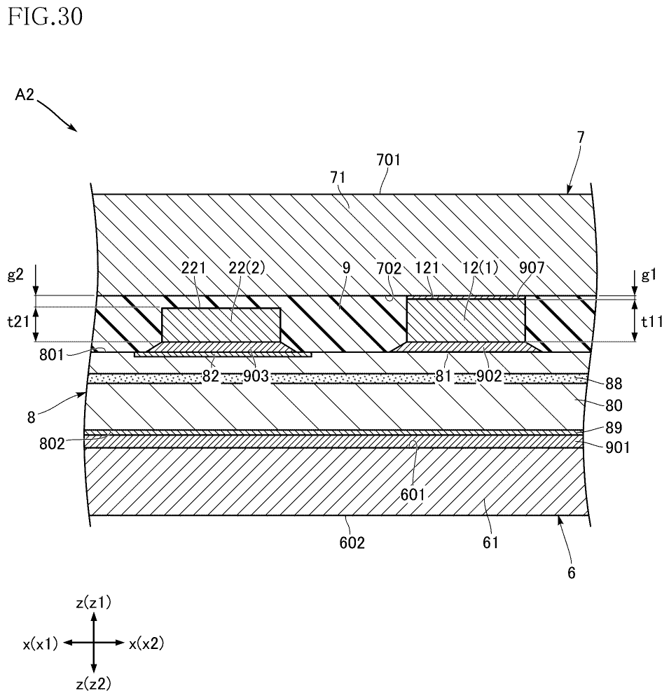

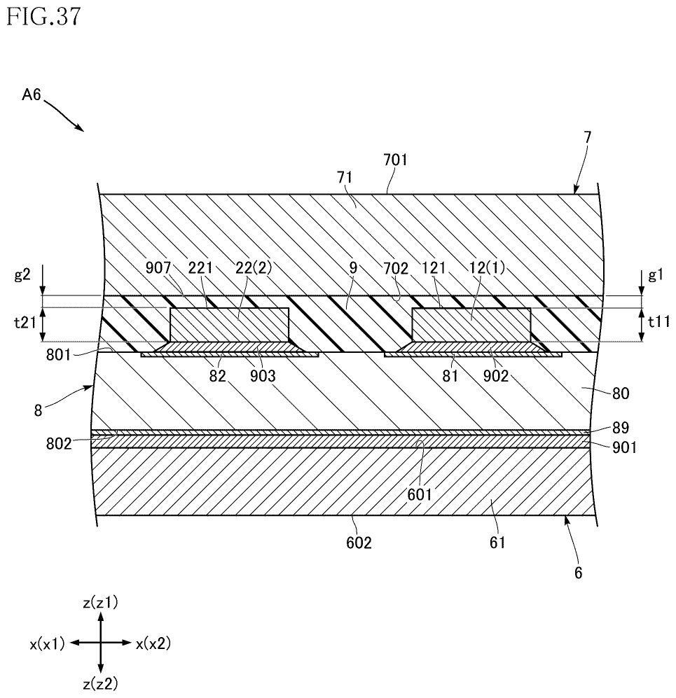

FIGS. 36 and 37 show a semiconductor device according to a sixth embodiment of the present disclosure. FIGS. 36 and 37 correspond to FIGS. 16 and 17, which show the first embodiment, or FIGS. 29 and 30, which show the second embodiment. In the semiconductor device A6 of the present embodiment, the space between the surfaces 121 and 221 of the comb portions 12 and 22 and the heat dissipation reverse face 702 of the main portion 71 of the heat dissipation member 7 is filled with a part of the sealing resin 9. That is, neither the surfaces 121 of the comb portions 12 nor the surfaces 221 of the comb portions 22 are bonded to the heat dissipation reverse face 702.

In the present embodiment again, the heat dissipation member 7 is conductively bonded to the island lead 6. Specifically, the support portion 72 and the support portion 73 are conductively bonded to the obverse face 601 via the sixth conductive bond portions 906.

According to the present embodiment again, heat from the semiconductor element 8 can be dissipated more efficiently. As understood from the present embodiment, the heat dissipation member 7 may be bonded neither the drain lead 1 nor the source lead 2.

### Seventh Embodiment

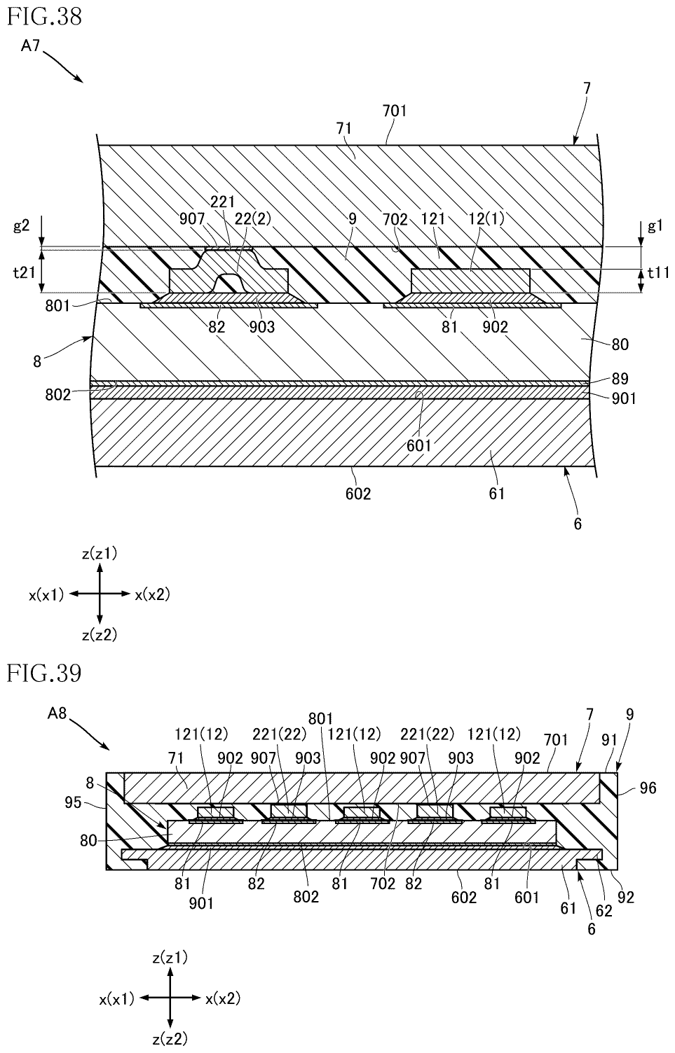

FIG. 38 shows a semiconductor device according to a seventh embodiment of the present disclosure. The semiconductor device A7 of the present embodiment differs from the embodiments described above in configuration of the comb portion 22.

The comb portion 22 of the present embodiment is bent as a whole as viewed in the second direction y orthogonal to the thickness direction y. The central part of the comb portion 22 in the first direction x is located on the z1 side in the thickness direction z from the opposite side portions in the first direction x. The central part forms the surface 221. Such a comb section 22 is formed, for example, by bending a metal plate having the same thickness as the thickness t11 of the main portion 21.

According to the present embodiment again, heat from the semiconductor element 8 can be dissipated more efficiently. As understood from present embodiment, the specific way of making the surface 121 and the surface 221 differ from each other in position in the thickness direction z is not limited in any way.

### Eighth Embodiment

FIG. 39 shows a semiconductor device according to an eighth embodiment of the present disclosure. The semiconductor device A8 of the present embodiment differs from the embodiments described above in configuration of the heat dissipation member 7.

The heat dissipation member 7 of the present embodiment has the main portion 71, but does not have the support portion 72 and the support portion 73. The heat dissipation member 7 is electrically connected to the source electrode 82 of the semiconductor element 8 by bonding the heat dissipation reverse face 702 of the main portion 71 to the surfaces 221 via the seventh conductive bonding portions 907. The heat dissipation member 7 is not bonded to the island lead 6.

According to the present embodiment again, heat from the semiconductor element 8 can be dissipated more efficiently. As understood from the present embodiment, the heat dissipation member 7 may not be bonded to the island lead 6.

The semiconductor device according to the present disclosure is not limited to the above-described embodiments. Various modifications in design may be made freely in the specific structure of each part of the semiconductor device according to the present disclosure. The present disclosure includes the embodiments described in the following clauses.

### Clause 1A.

A semiconductor device comprising:
a plurality of leads;
a semiconductor element;
a sealing resin covering at least a part of each of the plurality of leads, and the semiconductor element; and
a heat dissipation member, wherein
the semiconductor element includes a first electrode and a second electrode that are disposed on a first side in a thickness direction,
the plurality of leads include a first lead, a second lead, and an island lead,
the semiconductor element is mounted on the first side in the thickness direction of the island lead,
the first lead includes a first comb portion bonded to the first electrode and including a first face facing the first side in the thickness direction,
the second lead includes a second comb portion bonded to the second electrode and including a second face facing the first side in the thickness direction,
the first face is located on the first side in the thickness direction from the second face, and
the heat dissipation member is bonded to the first face and exposed from the sealing resin.

### Clause 2A.

The semiconductor device according to clause 1A, wherein the heat dissipation member is bonded to the island lead and exposed from the sealing resin on the first side in the thickness direction relative to the semiconductor element.

### Clause 3A.

The semiconductor device according to clause 2A, wherein the heat dissipation member includes a main portion located on the first side in the thickness direction relative to the semiconductor element and a support portion extending from the main portion to a second side in the thickness direction, and
the support portion is bonded to the island lead.

### Clause 4A.

The semiconductor device according to clause 3A, wherein the main portion overlaps with the semiconductor element as viewed in the thickness direction.

### Clause 5A.

The semiconductor device according to clause 3A or 4A, wherein the heat dissipation member includes two support portions located on opposite sides of the semiconductor element in a first direction orthogonal to the thickness direction.

### Clause 6A.

The semiconductor device according to any one of clauses 3A to 5A, wherein the sealing resin includes a resin first face facing the first side in the thickness direction,
the main portion includes a heat dissipation obverse face facing the first side in the thickness direction, and
the heat dissipation obverse face and the resin first face are flush with each other.

### Clause 7A.

The semiconductor device according to clause 1A, wherein the heat dissipation member is spaced apart from the island lead.

### Clause 8A.

A semiconductor device comprising:
a plurality of leads;
a semiconductor element; and
a sealing resin covering at least a part of each of the plurality of leads, and the semiconductor element, wherein
the semiconductor element includes a first electrode and a second electrode that are disposed on a first side in a thickness direction,
the plurality of leads include a first lead, a second lead, and an island lead,
the semiconductor element is mounted on the first side in the thickness direction of the island lead,
the first lead includes a first comb portion bonded to the first electrode and including a first face facing the first side in the thickness direction,
the second lead includes a second comb portion bonded to the second electrode and including a second face facing the first side in the thickness direction,
the first face is located on the first side in the thickness direction from the second face, and
the first face is exposed from the sealing resin.

### Clause 9A.

The semiconductor device according to any one of clauses 1A to 8A, wherein a thickness of the first comb portion in the thickness direction is larger than a thickness of the second comb portion in the thickness direction.

### Clause 10A.

The semiconductor device according to any one of clauses 1A to 8A, wherein the first comb portion is bent as viewed in a direction orthogonal to the thickness direction.

### Clause 11A.

The semiconductor device according to any one of clauses 1A to 10A, wherein the semiconductor element includes a source electrode and a drain electrode that are disposed on the first side in the thickness direction, and
the island lead includes an obverse face on which the semiconductor element is mounted and a reverse face exposed from the sealing resin, the island lead being electrically connected to the source electrode.

### Clause 12A.

The semiconductor device according to clause 11A, wherein the first lead is a source lead bonded to the source electrode, and
the island lead is electrically connected to the source electrode via the source lead.

### Clause 13A.

The semiconductor device according to clause 12A, wherein the plurality of leads include a source terminal lead bonded to the first lead, and
the island lead and the source terminal lead are connected to each other.

### Clause 14A.

The semiconductor device according to any one of clauses 1A to 10A, wherein the semiconductor element includes a source electrode and a drain electrode that are disposed on the first side in the thickness direction, and
the island lead includes an obverse face on which the semiconductor element is mounted and a reverse face exposed from the sealing resin, the island lead being electrically connected to the drain electrode.

### Clause 15A.

The semiconductor device according to clause 14A, wherein the first lead is a drain lead bonded to the drain electrode, and
the island lead is electrically connected to the drain electrode via the drain lead.

### Clause 16A.

The semiconductor device according to clause 15A, wherein the plurality of leads include a drain terminal lead bonded to the drain lead, and
the island lead and the drain terminal lead are connected to each other.

### Clause 17A.

The semiconductor device according to any one of clauses 1A to 16A, wherein the semiconductor element contains GaN.

### Clause 1B.

A semiconductor device comprising:
a plurality of leads;
a semiconductor element;
a sealing resin covering at least a part of each of the plurality of leads, and the semiconductor element; and
a heat dissipation member, wherein
the plurality of leads include an island lead, the semiconductor element being mounted on a first side in a thickness direction of the island lead, and
the heat dissipation member is bonded to the island lead and exposed from the sealing resin on the first side in the thickness direction relative to the semiconductor element.

### Clause 2B.

The semiconductor device according to clause 1B, wherein the heat dissipation member includes a main portion located on the first side in the thickness direction relative to the semiconductor element and a support portion extending from the main portion to a second side in the thickness direction, and
the support portion is bonded to the island lead.

### Clause 3B.

The semiconductor device according to clause 2B, wherein the main portion overlaps with the semiconductor element as viewed in the thickness direction.

### Clause 4B.

The semiconductor device according to clause 2B or 3B, wherein the heat dissipation member includes two support portions located on opposite sides of the semiconductor element in a first direction orthogonal to the thickness direction.

### Clause 5B.

The semiconductor device according to any one of clauses 2B to 4B, wherein the sealing resin includes a resin first face facing the first side in the thickness direction,
the main portion includes a heat dissipation obverse face facing the first side in the thickness direction, and
the heat dissipation obverse face and the resin first face are flush with each other.

### Clause 6B.

The semiconductor device according to any one of clauses 1B to 5B, wherein the semiconductor element includes a first electrode and a second electrode that are disposed on the first side in the thickness direction,
the plurality of leads include a first lead and a second lead,
the first lead includes a first comb portion bonded to the first electrode and including a first face facing the first side in the thickness direction,
the second lead includes a second comb portion bonded to the second electrode and including a second face facing the first side in the thickness direction,
the first face is located on the first side in the thickness direction from the second face, and
the heat dissipation member is bonded to the first face.

### Clause 7B.

The semiconductor device according to clause 6B, wherein a thickness of the first comb portion in the thickness direction is larger than a thickness of the second comb portion in the thickness direction.

### Clause 8B.

The semiconductor device according to clause 6B, wherein the first comb portion is bent as viewed in a direction orthogonal to the thickness direction.

### Clause 9B.

The semiconductor device according to any one of clauses 6B to 8B, wherein the semiconductor element includes a source electrode and a drain electrode that are disposed on the first side in the thickness direction, and
the island lead includes an obverse face on which the semiconductor element is mounted and a reverse face exposed from the sealing resin, the island lead being electrically connected to the source electrode.

### Clause 10B.

The semiconductor device according to clause 9B, wherein the first lead is a source lead bonded to the source electrode, and
the island lead is electrically connected to the source electrode via the source lead.

### Clause 11B.

The semiconductor device according to clause 10B, wherein the plurality of leads include a source terminal lead bonded to the first lead, and
the island lead and the source terminal lead are connected to each other.

### Clause 12B.

The semiconductor device according to any one of clauses 6B to 8B, wherein the semiconductor element includes a source electrode and a drain electrode that are disposed on the first side in the thickness direction, and
the island lead includes an obverse face on which the semiconductor element is mounted and a reverse face exposed from the sealing resin, the island lead being electrically connected to the drain electrode.

### Clause 13B.

The semiconductor device according to clause 12B, wherein the first lead is a drain lead bonded to the drain electrode, and
the island lead is electrically connected to the drain electrode via the drain lead.

### Clause 14B.

The semiconductor device according to clause 13B, wherein the plurality of leads include a drain terminal lead bonded to the drain lead, and
the island lead and the drain terminal lead are connected to each other.

### Clause 15B.

The semiconductor device according to clause 14B, wherein the drain terminal lead is exposed from the sealing resin.

### Clause 16B.

The semiconductor device according to any one of clauses 12B to 15B, wherein the semiconductor element includes a high-resistance layer located on a second side in the thickness direction relative to the source electrode.

### Clause 17B.

The semiconductor device according to any one of clauses 1B to 16B, wherein the semiconductor element contains GaN.

### REFERENCE NUMERALS

A1, A2, A3, A4, A5, A6, A7, A8: Semiconductor device 1: Drain lead 2: Source lead 3: Drain terminal lead 4: Source terminal lead 5: Gate terminal lead 6: Island lead 7: Heat dissipation member 8: Semiconductor element 9: Sealing resin 11: Main portion 12: Comb portion 15: Connecting portion 16: Bond portion 21: Main portion 22: Comb portion 25: Connecting portion 26: Bond portion 31: Thick portion 32: Thin portion 33: Extended portion 34: Extended portion 39: Relay portion 41: Thick portion 42: Thin portion 43: Extended portion 44: Extended portion 49: Relay portion 51: Thick portion 52: Thin portion 53: Extended portion 54: Extended portion 61: Thick portion 62: Thin portion 63: Extended portion 71: Main portion 72,73: Support portion 80: Element body 81: Drain electrode 82: Source electrode 83: Gate electrode 88: High-resistance layer 89: Metal layer 91: Resin first face 92: Resin second face 93: Resin third face 94: Resin fourth face 95: Resin fifth face 96: Resin sixth face 111: Surface 121: Surface 122: Distal end face 211: Surface 221: Surface 222: Distal end face 301: Obverse face 302: Reverse face 331: End face 341: End face 401: Obverse face 402: Reverse face 431: End face 441: End face 501: Obverse face 502: Reverse face 531: End face 541: End face 601: Obverse face 602: Reverse face 631: End face 701: Heat dissipation obverse face 702: Heat dissipation reverse face 711: Recess 801: Element obverse face 802: Element reverse face 901: First conductive bond portion 902: Second conductive bond portion 903: Third conductive bond portion 904: Fourth conductive bonding portion 905: Fifth conductive bonding portion 906: Sixth conductive bond portion 907: Seventh conductive bonding portion 909: Wire B1: DC/DC converter b11: Power supply b12: Controller b13: Inductor b14: Capacitor b15: Load b20: Semiconductor device g1, g2: Gap t10, t11, t20, t21: Thickness x: First direction y: Second direction z: Thickness direction

1. A semiconductor device comprising:
a plurality of leads;
a semiconductor element;
a sealing resin covering at least a part of each of the plurality of leads, and the semiconductor element; and
a heat dissipation member, wherein
the plurality of leads include an island lead, the semiconductor element being mounted on a first side in a thickness direction of the island lead, and
the heat dissipation member is bonded to the island lead and exposed from the sealing resin on the first side in the thickness direction relative to the semiconductor element.

2. The semiconductor device according to claim 1, wherein the semiconductor element includes a first electrode and a second electrode that are disposed on the first side in the thickness direction,
the plurality of leads include a first lead and a second lead,
the first lead includes a first comb portion bonded to the first electrode and including a first face facing the first side in the thickness direction,
the second lead includes a second comb portion bonded to the second electrode and including a second face facing the first side in the thickness direction,
the first face is located on the first side in the thickness direction from the second face, and
the heat dissipation member is bonded to the first face.

3. A semiconductor device comprising:
a plurality of leads;
a semiconductor element;
a sealing resin covering at least a part of each of the plurality of leads, and the semiconductor element; and
a heat dissipation member, wherein
the semiconductor element includes a first electrode and a second electrode that are disposed on a first side in a thickness direction,
the plurality of leads include a first lead, a second lead, and an island lead,
the semiconductor element is mounted on the first side in the thickness direction of the island lead,
the first lead includes a first comb portion bonded to the first electrode and including a first face facing the first side in the thickness direction,
the second lead includes a second comb portion bonded to the second electrode and including a second face facing the first side in the thickness direction,
the first face is located on the first side in the thickness direction from the second face, and
the heat dissipation member is bonded to the first face and exposed from the sealing resin.

4. The semiconductor device according to claim 3, wherein the heat dissipation member is bonded to the island lead and exposed from the sealing resin on the first side in the thickness direction relative to the semiconductor element.

5. The semiconductor device according to claim 1, wherein the heat dissipation member includes a main portion located on the first side in the thickness direction relative to the semiconductor element and a support portion extending from the main portion to a second side in the thickness direction, and
the support portion is bonded to the island lead.

6. The semiconductor device according to claim 5, wherein the main portion overlaps with the semiconductor element as viewed in the thickness direction.

7. The semiconductor device according to claim 5, wherein the heat dissipation member includes two support portions located on opposite sides of the semiconductor element in a first direction orthogonal to the thickness direction.

8. The semiconductor device according to claim 5, wherein the sealing resin includes a resin first face facing the first side in the thickness direction,
the main portion includes a heat dissipation obverse face facing the first side in the thickness direction, and
the heat dissipation obverse face and the resin first face are flush with each other.

9. A semiconductor device comprising:
a plurality of leads;
a semiconductor element; and
a sealing resin covering at least a part of each of the plurality of leads, and the semiconductor element, wherein
the semiconductor element includes a first electrode and a second electrode that are disposed on a first side in a thickness direction,
the plurality of leads include a first lead, a second lead, and an island lead,
the semiconductor element is mounted on the first side in the thickness direction of the island lead,
the first lead includes a first comb portion bonded to the first electrode and including a first face facing the first side in the thickness direction,
the second lead includes a second comb portion bonded to the second electrode and including a second face facing the first side in the thickness direction,
the first face is located on the first side in the thickness direction from the second face, and
the first face is exposed from the sealing resin.

10. The semiconductor device according to claim 1, wherein the semiconductor element includes a source electrode and a drain electrode that are disposed on the first side in the thickness direction, and
the island lead includes an obverse face on which the semiconductor element is mounted and a reverse face exposed from the sealing resin, the island lead being electrically connected to the source electrode.

11. The semiconductor device according to claim 10, wherein the first lead is a source lead bonded to the source electrode, and
the island lead is electrically connected to the source electrode via the source lead.

12. The semiconductor device according to claim 11, wherein the plurality of leads include a source terminal lead bonded to the first lead, and
the island lead and the source terminal lead are connected to each other.

13. The semiconductor device according to claim 1, wherein the semiconductor element includes a source electrode and a drain electrode that are disposed on the first side in the thickness direction, and
the island lead includes an obverse face on which the semiconductor element is mounted and a reverse face exposed from the sealing resin, the island lead being electrically connected to the drain electrode.

14. The semiconductor device according to claim 13, wherein the first lead is a drain lead bonded to the drain electrode, and
the island lead is electrically connected to the drain electrode via the drain lead.

15. The semiconductor device according to claim 14, wherein the plurality of leads include a drain terminal lead bonded to the drain lead, and
the island lead and the drain terminal lead are connected to each other.

16. The semiconductor device according to claim 15, wherein the drain terminal lead is exposed from the sealing resin.

17. The semiconductor device according to claim 13, wherein the semiconductor element includes a high-resistance layer located on a second side in the thickness direction relative to the source electrode.

18. The semiconductor device according to claim 1, wherein the semiconductor element contains GaN.

19. The semiconductor device according to claim 2, wherein a thickness of the first comb portion in the thickness direction is larger than a thickness of the second comb portion in the thickness direction.

20. The semiconductor device according to claim 2, wherein the first comb portion is bent as viewed in a direction orthogonal to the thickness direction.
